(19) United States
(12) Patent Application Publication
(10) Pub. No.: US 2026/0305366 A1
(43) Pub. Date: Oct. 1, 2026

(54) SEMICONDUCTOR DEVICE

(71) Applicant: ROHM CO., LTD., Kyoto (JP)

(72) Inventor: Koji SAITO, Kyoto (JP)

(73) Assignee: ROHM CO., LTD., Kyoto (JP)

(21) Appl. No.: 19/564,824

(22) Filed: Mar. 12, 2026

(30) Foreign Application Priority Data
Mar. 28, 2025 (JP) 2025-056421

(51) Int. Cl. H10W 44/00; H10W 70/63; H10W 90/00; H10W 90/10; H02M 3/335

(52) U.S. Cl. CPC H10W 44/601; H10W 70/63; H10W 90/10; H10W 90/724; H10W 90/754; H02M 3/33576

(57) ABSTRACT

A semiconductor device includes a mounting substrate, a first semiconductor chip, and a second semiconductor chip. The first semiconductor chip is mounted on a first substrate surface of the mounting substrate. The second semiconductor chip is mounted on the first substrate surface of the mounting substrate at a gap from the first semiconductor. A plurality of first conductive layers are provided on the first substrate surface of the mounting substrate, and a plurality of second conductive layers are provided in the mounting substrate. The semiconductor device includes a first capacitor and a second capacitor that are electrically connected to the first semiconductor chip and the second semiconductor chip. The first capacitor and the second capacitor are constituted of the plurality of first conductive layers provided on the first substrate surface of the mounting substrate and the plurality of second conductive layers provided in the mounting substrate.

### CROSS REFERENCE TO RELATED APPLICATION

This application is based upon and claims the benefit of priority of the prior Japanese Patent Application No. 2025-056421, filed on March 28, 2025, the entire contents of which are incorporated herein by reference.

### TECHNICAL FIELD

The present disclosure relates to a semiconductor device.

### BACKGROUND ART

A signal transmission device that transmits a signal between a first circuit system and a second circuit system while electrically insulating the first circuit system from the second circuit system is used in various applications such as power supply devices and motor driving devices. An insulating gate driver that applies a gate voltage to the gate of a switching element such as a transistor is known as an example of a signal transmission device. Japanese Patent Application Laid-Open Publication No. 2018-78169 discloses a semiconductor module that includes chips that are DC-insulated and AC-connected by a transformer chip.

### SUMMARY OF THE INVENTION

However, in a semiconductor device in which a first circuit system is insulated from a second circuit system, further cost reduction can be considered.

A semiconductor device according to an aspect of the present disclosure includes: a mounting substrate including a first substrate surface and a second substrate surface on a side opposite to the first substrate surface; a first semiconductor chip mounted on the first substrate surface or the second substrate surface; a second semiconductor chip mounted on the first substrate surface or the second substrate surface, at a gap from the first semiconductor chip; a plurality of conductive layers provided on the first substrate surface; a plurality of conductive layers provided in the mounting substrate or on the second substrate surface; and a first capacitor and a second capacitor that are constituted of the plurality of conductive layers provided on the first substrate surface and the plurality of conductive layers provided in the mounting substrate or on the second substrate surface, and that are electrically connected to the first semiconductor chip and the second semiconductor chip.

### BRIEF DESCRIPTION OF THE DRAWINGS

FIG. 1 is a block circuit diagram showing a schematic configuration of a semiconductor device according to Embodiment 1.

FIG. 2 is a schematic plan view of the semiconductor device according to Embodiment 1.

FIG. 3 is a schematic cross-sectional view of the semiconductor device along the line F3-F3 of FIG. 2.

FIG. 4 is a magnified schematic plan view of a first capacitor and a second capacitor shown in FIG. 2.

FIG. 5 is a schematic cross-sectional view of the first capacitor and the second capacitor along the line F5-F5 of FIG. 4.

FIG. 6 is a schematic plan view of conductive layers and wiring lines provided on a first substrate surface of a mounting substrate shown in FIG. 4.

FIG. 7 is a schematic plan view of conductive layers and wiring lines provided inside the mounting substrate shown in FIG. 4.

FIG. 8 is a schematic cross-sectional view for describing the action of the semiconductor device of FIG. 2.

FIG. 9 is a schematic cross-sectional view for describing the action of a semiconductor device according to a comparison example.

FIG. 10 is a magnified schematic plan view of a portion of a semiconductor device according to Embodiment 2.

FIG. 11 is a schematic plan view of conductive layers and wiring lines provided on a first substrate surface of a mounting substrate shown in FIG. 10.

FIG. 12 is a schematic plan view of conductive layers and wiring lines provided inside the mounting substrate shown in FIG. 10.

FIG. 13 is a schematic cross-sectional view for describing the action of the semiconductor device of FIG. 10.

FIG. 14 is a circuit diagram showing a schematic configuration of a semiconductor device according to Embodiment 3.

FIG. 15 is a waveform chart for describing the operation of a semiconductor device shown in FIG. 17.

FIG. 16 is a waveform chart for describing the operation of the semiconductor device shown in FIG. 17.

FIG. 17 is a circuit diagram of a semiconductor device according to Embodiment 4.

FIG. 18 is a schematic cross-sectional view of a first capacitor and a second capacitor according to a modification example.

FIG. 19 is a schematic cross-sectional view of a semiconductor device according to a modification example.

FIG. 20 is a schematic cross-sectional view of a semiconductor device according to a modification example.

### DETAILED DESCRIPTION OF EMBODIMENTS

Some embodiments of a semiconductor device according to the present disclosure will be explained below with reference to attached drawings. In order to simplify and clarify the explanation, the constituent elements shown in the drawings are not necessarily depicted at a uniform scale. For ease of understanding, hatching lines are sometimes omitted from the cross-sectional views. The attached drawings are merely for the purpose of illustrating the embodiments of the present disclosure, and should not be interpreted as limiting the present disclosure. Language such as “first,” “second,” “third,” or the like in the present disclosure is used merely in order to distinguish objects, and is not necessarily intended to indicate the sequence of the objects.

The detailed description below includes a device, a system, and a method for implementing exemplary embodiments of the present disclosure. The detailed description is typically for the sole purpose of explanation, and is not intended to limit the embodiments of the present disclosure, or to limit application and use of such embodiments.

### Embodiment 1

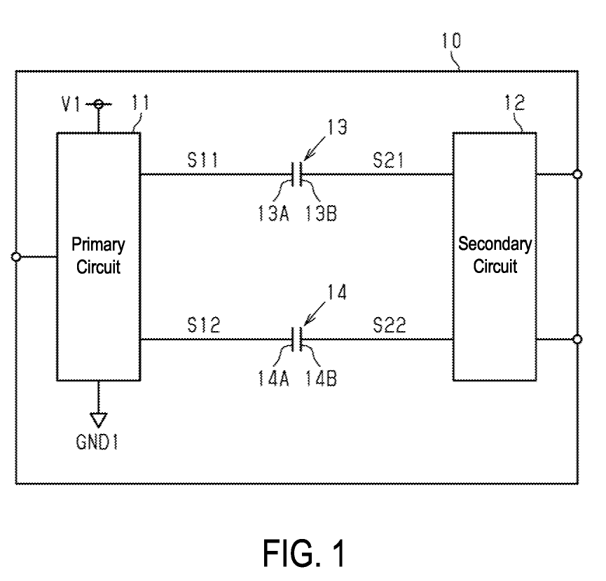

A semiconductor device 10 according to Embodiment 1 will be described below with reference to FIGS. 1 to 9.

The electric configuration of the semiconductor device 10 will be explained with reference to FIG. 1.

FIG. 1 is a circuit diagram showing a schematic configuration of the semiconductor device 10.

The semiconductor device 10 includes a primary circuit 11, a secondary circuit 12, a first capacitor 13, and a second capacitor 14.

The first capacitor 13 and the second capacitor 14 are connected in parallel between the primary circuit 11 and the secondary circuit 12. The secondary circuit 12 is connected to the primary circuit 11 via the first capacitor 13 and is also connected to the primary circuit 11 via the second capacitor 14.

The first capacitor 13 includes a first electrode 13A and a second electrode 13B. The first electrode 13A of the first capacitor 13 is connected to the primary circuit 11, and the second electrode 13B of the first capacitor 13 is connected to the secondary circuit 12. The second capacitor 14 includes a first electrode 14A and a second electrode 14B. The first electrode 14A of the second capacitor 14 is connected to the primary circuit 11, and the second electrode 14B of the second capacitor 14 is connected to the secondary circuit 12.

In the semiconductor device 10, the primary circuit 11 and the secondary circuit 12 are electrically insulated from each other by both the first capacitor 13 and the second capacitor 14. More specifically, the first capacitor 13 and the second capacitor 14 DC-insulate the primary circuit 11 from the secondary circuit 12, and allow the transmission of AC voltage between the primary circuit 11 and the secondary circuit 12. The first capacitor 13 and the second capacitor 14 are insulating elements that electrically insulate the primary circuit 11 from the secondary circuit 12, and allow the transmission of signals between the primary circuit 11 and the secondary circuit 12. That is, the semiconductor device 10 is configured such that the primary circuit 11 and the secondary circuit 12 are electrically insulated from each other by the first capacitor 13 and the second capacitor 14, and so as to allow transmission of AC voltage between the primary circuit 11 and the secondary circuit 12. The semiconductor device 10 is configured as an insulating DC-DC converter, an insulating switch, an insulating A/D converter circuit, or the like, for example.

The primary circuit 11 is configured so as to operate by an operating voltage V1. The primary circuit 11 is configured to output a first output signal S11 to the first capacitor 13 and output a second output signal S12 to the second capacitor 14. Also, the primary circuit 11 is configured to generate the first output signal S11 and the second output signal S12 as differential signals.

The secondary circuit 12 is configured to operate by a first input signal S21 transmitted by the first capacitor 13 and by a second input signal S22 transmitted by the second capacitor 14. The first input signal S21 and the second input signal S22 in the secondary circuit 12 are differential signals based on the first output signal S11 and the second output signal S12. The secondary circuit 12 is configured so as to operate by differential signals.

### Configuration of Semiconductor Device

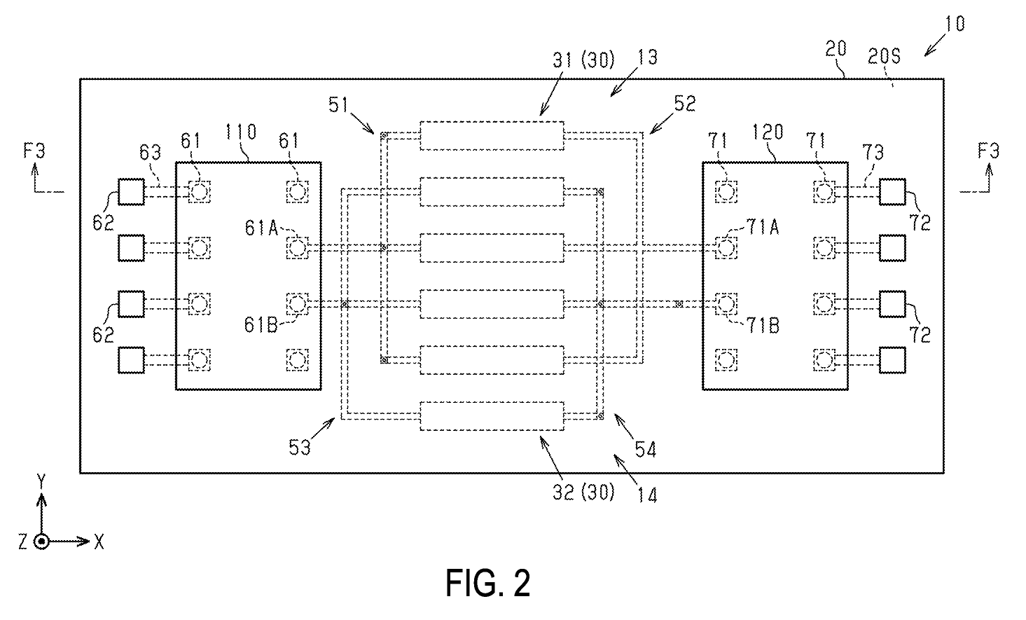

The configuration of the semiconductor device 10 will be explained with reference to FIGS. 2 to 7.

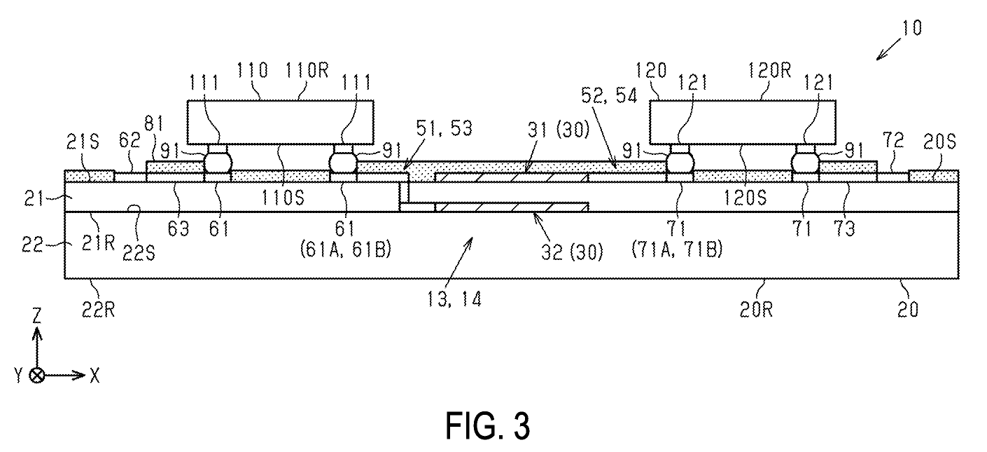

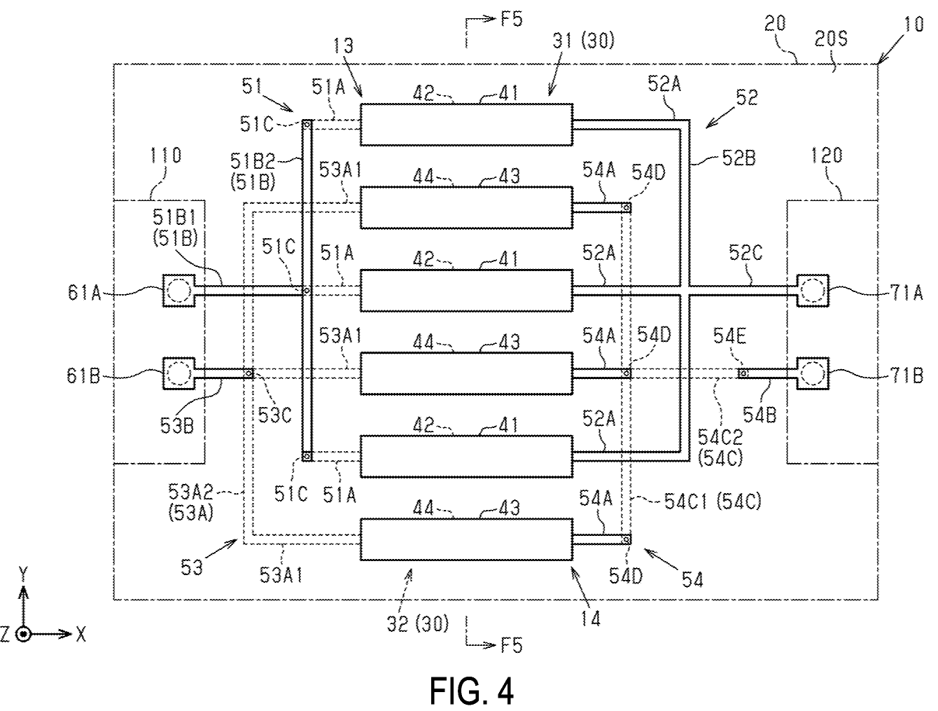

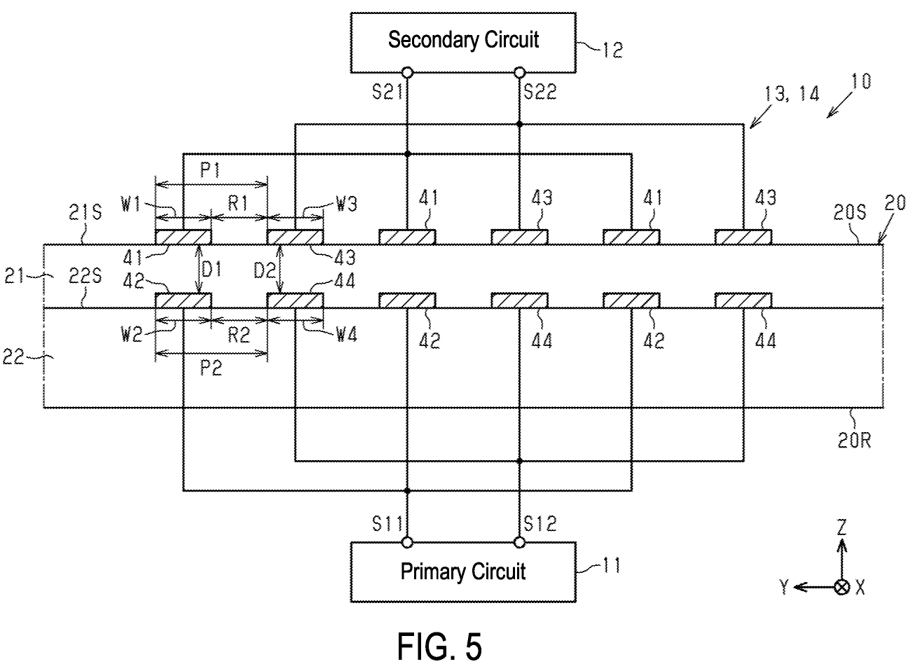

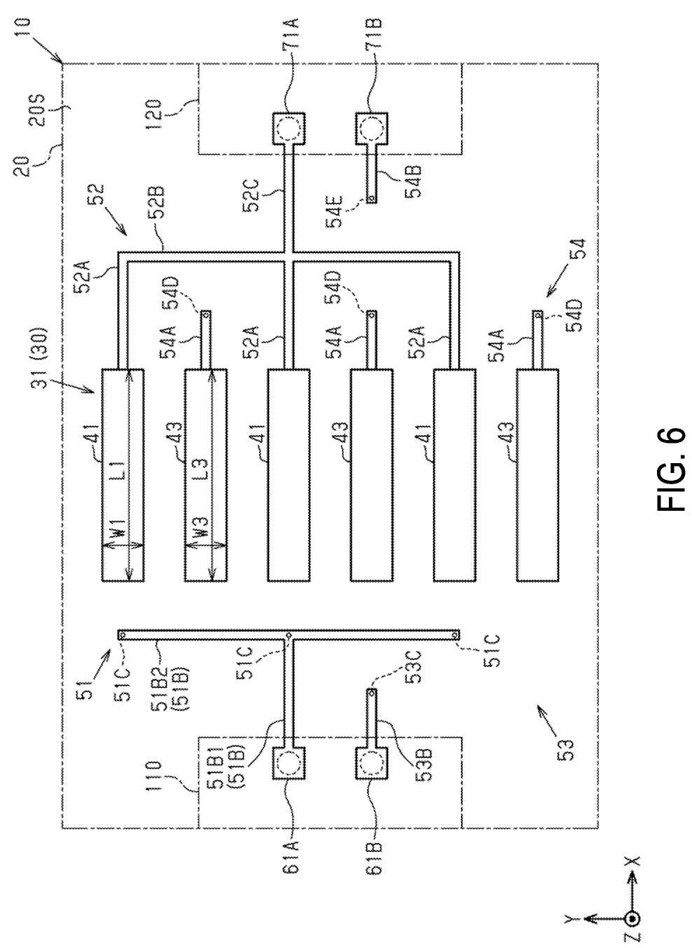

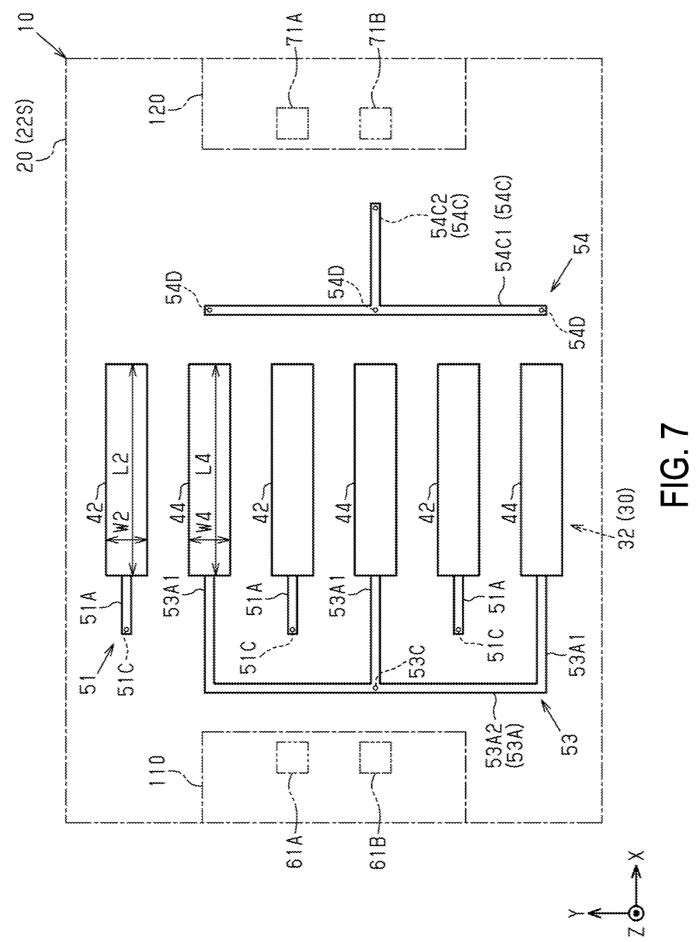

FIG. 2 is a schematic plan view schematically showing an example of the configuration of the semiconductor device 10. FIG. 3 is a schematic cross-sectional view of the semiconductor device 10 along the line F3-F3 of FIG. 2. FIG. 4 is a schematic plan view showing a portion of the semiconductor device 10 of FIG. 2, and shows the first capacitor 13, the second capacitor 14, connective wiring lines 51 to 54, and the like. FIG. 5 is a schematic cross-sectional view of conductive layers constituting the first capacitor 13 and the second capacitor 14 along the line F5-F5 of FIG. 4. FIG. 5 shows the connective state of a first semiconductor chip 110 and a second semiconductor chip 120 to the conductive layers of the first capacitor 13 and the second capacitor 14. FIG. 6 is a schematic plan view of conductive layers and wiring lines provided on a first substrate surface 20S of a mounting substrate 20 shown in FIG. 4. FIG. 7 is a schematic plan view of conductive layers and wiring lines provided inside the mounting substrate 20 shown in FIG. 4.

As shown in FIGS. 2 and 3, the semiconductor device 10 includes the mounting substrate 20, and the first semiconductor chip 110 and the second semiconductor chip 120 mounted on the mounting substrate 20.

The mounting substrate 20 has a rectangular plate shape. The first semiconductor chip 110 and the second semiconductor chip 120 have a rectangular plate shape.

FIGS. 2 and 3 show XYZ axes that are perpendicular to each other. In describing the semiconductor device 10, for ease of description, the thickness direction of the mounting substrate 20 is designated as a direction along the Z axis direction. The direction along the X axis is designated as a first direction X, the direction along the Y axis direction is designated as a second direction Y, and the direction along the Z axis direction is designated as a third direction Z. Also, the term “plan view” used in the description below indicates a view of an object (the semiconductor device 10 or constituent elements thereof) from the Z axis direction unless otherwise explicitly noted.

The mounting substrate 20 includes the first substrate surface 20S and a second substrate surface 20R opposite to the first substrate surface 20S. In one example, the first semiconductor chip 110 and the second semiconductor chip 120 are mounted on the first substrate surface 20S. The first semiconductor chip 110 and the second semiconductor chip 120 are arranged along the first direction X. The first semiconductor chip 110 and the second semiconductor chip 120 are disposed so as to have a gap therebetween in the first direction X.

### First Semiconductor Chip, Second Semiconductor Chip

The first semiconductor chip 110 includes a first surface 110S, and a second surface 110R opposite to the first surface 110S. The first surface 110S has provided thereon a plurality of connection electrodes 111. The first semiconductor chip 110 includes circuit elements constituting the primary circuit 11 shown in FIG. 1. The circuit elements of the first semiconductor chip 110 are electrically connected to the plurality of connection electrodes 111. The first semiconductor chip 110 is arranged such that the first surface 110S faces the first substrate surface 20S of the mounting substrate 20, and then mounted to the mounting substrate 20.

The second semiconductor chip 120 includes a first surface 120S, and a second surface 120R opposite to the first surface 120S. The first surface 120S has provided thereon a plurality of connection electrodes 121. The second semiconductor chip 120 includes circuit elements constituting the secondary circuit 12 shown in FIG. 1. The circuit elements of the second semiconductor chip 120 are electrically connected to the plurality of connection electrodes 121. The second semiconductor chip 120 is arranged such that the first surface 120S faces the first substrate surface 20S of the mounting substrate 20, and then mounted to the mounting substrate 20.

### Mounting Substrate

The mounting substrate 20 is made of an electrically insulating material. The mounting substrate 20 may be made of a synthetic resin material including an epoxy resin. The mounting substrate 20 may include a filler such as glass. In one example, the mounting substrate 20 is made of a glass epoxy resin.

As shown in FIGS. 3 and 5, the mounting substrate 20 may include a first insulating layer 21 and a second insulating layer 22 in one example. The first insulating layer 21 is provided over the second insulating layer 22. The first insulating layer 21 includes a first surface 21S, and a second surface 21R opposite to the first surface 21S. The second insulating layer 22 includes a first surface 22S, and a second surface 22R opposite to the first surface 22S. The second surface 21R of the first insulating layer 21 is in contact with the first surface 22S of the second insulating layer 22. The first surface 21S of the first insulating layer 21 constitutes the first substrate surface 20S of the mounting substrate 20. The second surface 22R of the second insulating layer 22 constitutes the second substrate surface 20R of the mounting substrate 20.

The first insulating layer 21 may be constituted of a plurality of insulating layers. The second insulating layer 22 may be constituted of a plurality of insulating layers. The first insulating layer 21 and the second insulating layer 22 may be made of the same material or of different materials. FIGS. 3 and 5 indicate the second surface 21R of the first insulating layer 21 and the first surface 22S of the second insulating layer 22 with a solid line for ease of description. The interface between the first insulating layer 21 and the second insulating layer 22 may be partially or entirely gone, and there are cases in which the boundary is unclear. Also, the mounting substrate 20 may be constituted of three or more insulating layers.

### First Capacitor, Second Capacitor

As shown in FIGS. 2 to 4, the semiconductor device 10 includes the first capacitor 13 and the second capacitor 14. The first capacitor 13 and the second capacitor 14 are disposed between the first semiconductor chip 110 and the second semiconductor chip 120 along the first direction X in which the first semiconductor chip 110 and the second semiconductor chip 120 are arranged.

The first capacitor 13 and the second capacitor 14 are constituted of a plurality of conductive layers 30 provided to the mounting substrate 20. The plurality of conductive layers 30 include a plurality of first conductive layers 31 provided on the first substrate surface 20S of the mounting substrate 20 and a plurality of second conductive layers 32 provided in the mounting substrate 20. As shown in FIGS. 3 and 5, the plurality of second conductive layers 32 are provided on the first surface 22S of the second insulating layer 22.

The plurality of first conductive layers 31 include a plurality of first conductive layers 41 and a plurality of third conductive layers 43. The plurality of first conductive layers 41 and the plurality of third conductive layers 43 have a rectangular shape in a plan view. The plurality of first conductive layers 41 and the plurality of third conductive layers 43 have a rectangular shape that is elongated in the first direction X along which the first semiconductor chip 110 and the second semiconductor chip 120 are arrayed. The plurality of first conductive layers 41 and the plurality of third conductive layers 43 are arranged alternately along the second direction Y, which is perpendicular to the first direction X. The plurality of first conductive layers 41 and the plurality of third conductive layers 43 have the same size in one example.

The plurality of second conductive layers 32 include a plurality of second conductive layers 42 and a plurality of fourth conductive layers 44. The plurality of second conductive layers 42 and the plurality of fourth conductive layers 44 have a rectangular shape in a plan view. The plurality of second conductive layers 42 and the plurality of fourth conductive layers 44 have a rectangular shape that is elongated in the first direction X along which the first semiconductor chip 110 and the second semiconductor chip 120 are arrayed. The plurality of second conductive layers 42 and the plurality of fourth conductive layers 44 are arranged alternately along the second direction Y, which is perpendicular to the first direction X. The plurality of second conductive layers 42 and the plurality of fourth conductive layers 44 have the same size in one example.

The plurality of first conductive layers 41 and the plurality of second conductive layers 42 have the same size in one example. The plurality of first conductive layers 41 and the plurality of second conductive layers 42 are arranged so as to overlap each other in the third direction Z. The plurality of first conductive layers 41 and the plurality of second conductive layers 42 oppose each other in the third direction Z.

The plurality of third conductive layers 43 and the plurality of fourth conductive layers 44 have the same size in one example. The plurality of third conductive layers 43 and the plurality of fourth conductive layers 44 are arranged so as to overlap each other in the third direction Z. The plurality of third conductive layers 43 and the plurality of fourth conductive layers 44 oppose each other in the third direction Z.

The first capacitor 13 is constituted of the plurality of first conductive layers 41 and the plurality of second conductive layers 42 that oppose each other in the third direction Z. The first capacitor 13 is constituted of the plurality of first conductive layers 41 provided on the first substrate surface 20S of the mounting substrate 20 and the plurality of second conductive layers 42 provided in the mounting substrate 20.

The second capacitor 14 is constituted of the plurality of third conductive layers 43 and the plurality of fourth conductive layers 44 that oppose each other in the third direction Z. The second capacitor 14 is constituted of the plurality of third conductive layers 43 provided on the first substrate surface 20S of the mounting substrate 20 and the plurality of fourth conductive layers 44 provided in the mounting substrate 20.

As shown in FIGS. 5 and 6, the plurality of first conductive layers 41 have a first length L1 in the first direction X and a first width W1 in the second direction Y. The plurality of third conductive layers 43 have a third length L3 in the first direction X and a third width W3 in the second direction Y. In one example, the first length L1 is equal to the third length L3. In one example, the first width W1 is equal to the third width W3.

The plurality of first conductive layers 41 and the plurality of third conductive layers 43 are arrayed in the second direction Y at a first pitch P1. In one example, a first gap R1 between the first conductive layer 41 and the third conductive layer 43 is greater than the first width W1.

As shown in FIGS. 5 and 7, the plurality of second conductive layers 42 have a second length L2 in the first direction X and a second width W2 in the second direction Y. In one example, the second length L2 is equal to the first length L1. In one example, the second width W2 is equal to the first width W1.

The plurality of fourth conductive layers 44 have a fourth length L4 in the first direction X and a fourth width W4 in the second direction Y. In one example, the fourth length L4 is equal to the third length L3. In one example, the fourth width W4 is equal to the third width W3. In one example, the fourth length L4 is equal to the second length L2. In one example, the fourth width W4 is equal to the second width W2.

The plurality of second conductive layers 42 and the plurality of fourth conductive layers 44 are arrayed in the second direction Y at a second pitch P2. In one example, the second pitch P2 is equal to the first pitch P1, and in one example, a second gap R2 between the second conductive layer 42 and the fourth conductive layer 44 is greater than the second width W2. In one example, the second gap R2 is equal to the first gap R1.

The first capacitor 13 has a capacitance based on the shapes and arrangement positions of the plurality of first conductive layers 41 and the plurality of second conductive layers 42. The capacitance of the first capacitor 13 may be 20pF to 200pF, inclusive. The first width W1, the second width W2, the first length L1, the second length L2, and a distance D1 between the plurality of first conductive layers 41 and the plurality of second conductive layers 42 may be set according to the necessary capacitance for the first capacitor 13. The distance D1 may be set to be greater than the first pitch P1 of the plurality of first conductive layers 31 (plurality of first conductive layers 41 and plurality of third conductive layers 43). The distance D1 may be set to be less than or equal to the first pitch P1 of the plurality of first conductive layers 31 (plurality of first conductive layers 41 and plurality of third conductive layers 43).

The second capacitor 14 has a capacitance based on the shapes and arrangement positions of the plurality of third conductive layers 43 and the plurality of fourth conductive layers 44. The capacitance of the second capacitor 14 may be 20pF to 200pF, inclusive. The third width W3, the fourth width W4, the third length L3, the fourth length L4, and a distance D2 between the plurality of third conductive layers 43 and the plurality of fourth conductive layers 44 may be set according to the necessary capacitance for the second capacitor 14. The distance D2 may be set to be greater than the first pitch P1 of the plurality of first conductive layers 31 (plurality of first conductive layers 41 and plurality of third conductive layers 43). The distance D2 may be set to be less than or equal to the first pitch P1 of the plurality of first conductive layers 31 (plurality of first conductive layers 41 and plurality of third conductive layers 43).

### Mounting Pads

As shown in FIGS. 2 and 3, a plurality of first connection pads 61 are provided on the first substrate surface 20S of the mounting substrate 20. The plurality of first connection pads 61 are provided in order to mount the first semiconductor chip 110. The plurality of connection electrodes 111 of the first semiconductor chip 110 are electrically connected to the plurality of first connection pads 61 by a conductive joining material 91 such as solder.

A plurality of second connection pads 71 are provided on the first substrate surface 20S of the mounting substrate 20. The plurality of second connection pads 71 are provided in order to mount the second semiconductor chip 120. The plurality of connection electrodes 121 of the second semiconductor chip 120 are electrically connected to the plurality of second connection pads 71 by a conductive joining material 91 such as solder.

### External Connection Pads, External Connection Wiring Lines

A plurality of first external connection pads 62 are provided on the first substrate surface 20S of the mounting substrate 20. The plurality of first external connection pads 62 are provided on the side of the first semiconductor chip 110 opposite to the side facing the second semiconductor chip 120. The plurality of first external connection pads 62 may be provided in order to make an external connection for the semiconductor device 10. The plurality of first external connection pads 62 are electrically connected to the plurality of first connection pads 61 by a plurality of external connection wiring lines 63. The plurality of first external connection pads 62 are electrically connected to the first semiconductor chip 110 by the plurality of external connection wiring lines 63 and the plurality of first connection pads 61. The plurality of first external connection pads 62 may be used in order to supply the operating voltage V1 shown in FIG. 1, a reference potential, or the like to the first semiconductor chip 110.

A plurality of second external connection pads 72 are provided on the first substrate surface 20S of the mounting substrate 20. The plurality of second external connection pads 72 are provided on the side of the second semiconductor chip 120 opposite to the side facing the first semiconductor chip 110. The plurality of second external connection pads 72 may be provided in order to make an external connection for the semiconductor device 10. The plurality of second external connection pads 72 are electrically connected to the plurality of second connection pads 71 by a plurality of external connection wiring lines 73. The plurality of second external connection pads 72 are electrically connected to the second semiconductor chip 120 by the plurality of external connection wiring lines 73 and the plurality of second connection pads 71. The plurality of second external connection pads 72 may be used in order to make an external connection for the second semiconductor chip 120.

### Connective Wiring Lines

As shown in FIGS. 2 to 7, the semiconductor device 10 includes a first connective wiring line 51 that electrically connects the first semiconductor chip 110 to the first capacitor 13, and a second connective wiring line 52 that electrically connects the first capacitor 13 to the second semiconductor chip 120.

As shown in FIGS. 4, 6, and 7, the first connective wiring line 51 electrically connects the plurality of second conductive layers 42 constituting the first capacitor 13 to one first connection pad 61A among the plurality of first connection pads 61 on which the first semiconductor chip 110 is mounted. The second connective wiring line 52 electrically connects the plurality of first conductive layers 41 constituting the first capacitor 13 to one second connection pad 71A among the plurality of second connection pads 71 on which the second semiconductor chip 120 is mounted.

The first connective wiring line 51 includes a plurality of wiring units 51A connected to the plurality of second conductive layers 52, a wiring unit 51B connected to the first connection pad 61A, and a plurality of vias 51C connecting the plurality of wiring units 51A and the wiring unit 51B. The plurality of wiring units 51A are provided on the first surface 22S (see FIG. 7) of the second insulating layer 22. The wiring unit 51B is provided on the first surface 21S (see FIG. 6) of the first insulating layer 21. The plurality of wiring units 51A extend in the first direction X from each of the plurality of second conductive layers 42 towards the first semiconductor chip 110 in a plan view. The wiring unit 51B includes a first wiring section 51B1 that extends from the first connection pad 61A in the first direction X, and a second wiring section 51B2 that is connected to the tip of the first wiring section 51B1 and extends in the second direction Y. The plurality of vias 51C connect the tips of the plurality of wiring units 51A to the second wiring section 51B2 of the wiring unit 51B.

The second connective wiring line 52 is provided on the first surface 21S of the first insulating layer 21. The second connective wiring line 52 includes a plurality of wiring sections 52A that extend from the plurality of first conductive layers 41 in the first direction X, a wiring section 52B that extends in the second direction Y and connects the tips of the plurality of wiring sections 52A, and a wiring section 52C that connects the wiring section 52B to the second connection pad 71A.

The semiconductor device 10 includes a third connective wiring line 53 that electrically connects the first semiconductor chip 110 to the second capacitor 14, and a fourth connective wiring line 54 that electrically connects the second capacitor 14 to the second semiconductor chip 120.

As shown in FIGS. 4, 6, and 7, the third connective wiring line 53 electrically connects the plurality of fourth conductive layers 44 constituting the second capacitor 14 to one first connection pad 61B among the plurality of first connection pads 61 on which the first semiconductor chip 110 is mounted. The fourth connective wiring line 54 electrically connects the plurality of third conductive layers 43 constituting the second capacitor 14 to one second connection pad 71B among the plurality of second connection pads 71 on which the second semiconductor chip 120 is mounted.

The third connective wiring line 53 includes a wiring unit 53A connected to the plurality of fourth conductive layers 44, a wiring unit 53B connected to the first connection pad 61B, and a via 53C that connects the wiring unit 53A and the wiring unit 53B. The wiring unit 53A is provided on the first surface 22S (see FIG. 7) of the second insulating layer 22. The wiring unit 53B is provided on the first surface 21S of the first insulating layer 21. The wiring unit 53A includes a plurality of first wiring sections 53A1 that extend from each of the plurality of fourth conductive layers 44 towards the first semiconductor chip 110 in a plan view, and a second wiring section 53A2 that extends in the second direction Y and is connected to the tips of the plurality of first wiring sections 53A1. The wiring unit 53B extends from the first connection pad 61B towards the second semiconductor chip 120. The tip of the wiring unit 53B connected to the first connection pad 61B is positioned further towards the first semiconductor chip 110 (first connection pad 61B) than the second wiring section 51B2 of the first connective wiring line 51. The via 53C connects the tip of the wiring unit 53B to the second wiring section 53A2.

The fourth connective wiring line 54 includes a plurality of wiring units 54A connected to the plurality of fourth conductive layers 44, a wiring unit 54B connected to the second connection pad 71B, a wiring unit 54C positioned between the plurality of wiring units 54A and the wiring unit 54B in a plan view, a plurality of vias that connect the plurality of wiring units 54A to the wiring unit 54C, and a via 54E connecting the wiring unit 54B to the wiring unit 54C.

The plurality of wiring units 54A and the wiring unit 54B are provided on the first surface 21S of the first insulating layer 21. The wiring unit 54C is provided on the first surface 22S of the second insulating layer 22.

The tip of the plurality of wiring units 54A is positioned further towards the first semiconductor chip 110 (plurality of third conductive layers 43) than the wiring section 52B of the second connective wiring line 52. The wiring unit 54B extends from the second connection pad 71B towards the first semiconductor chip 110. The tip of the wiring unit 54B is positioned further towards the second semiconductor chip 120 (second connection pad 71B) than the wiring section 52B of the second connective wiring line 52.

The wiring unit 54C includes a first wiring section 54C1 that extends in the second direction Y and is arranged so as to overlap the tips of the plurality of wiring units 54A in a plan view, and a second wiring section 54C2 that extends from the first wiring section 54C1 towards the second connection pad 71B in a plan view. The plurality of vias 54D connect the tips of the plurality of wiring units 54A to the first wiring section 54C1. The via 54E connects the tip of the second wiring section 54C2 to the tip of the wiring unit 54B. The wiring unit 54C and the vias 54D and 54E constitute a bypass section that bypasses the second connective wiring line 52.

As shown in FIG. 3, a resist film 81 may be provided on the first substrate surface 20S of the mounting substrate 20. The resist film 81 may cover the first substrate surface 20S of the mounting substrate 20, the plurality of first conductive layers 31, the connective wiring lines 51 to 54, and the external connection wiring lines 63 and 73. The resist film 81 may be provided so as to expose the connection pads 61 and 71 and the external connection pads 62 and 72. Also, a resist film that covers the second substrate surface 20R of the mounting substrate 20 may be provided.

### Action of Embodiment 1

The semiconductor device 10 includes the mounting substrate 20, the first semiconductor chip 110, and the second semiconductor chip 120. The mounting substrate 20 includes the first substrate surface 20S and the second substrate surface 20R opposite to the first substrate surface 20S. The first semiconductor chip 110 is mounted on the first substrate surface 20S of the mounting substrate 20. The second semiconductor chip 120 is mounted on the first substrate surface 20S of the mounting substrate 20 at a gap from the first semiconductor chip 110. The plurality of first conductive layers 31 are provided on the first substrate surface 20S of the mounting substrate 20, and the plurality of second conductive layers 32 are provided in the mounting substrate 20. The semiconductor device 10 includes the first capacitor 13 and the second capacitor 14 that are electrically connected to the first semiconductor chip 110 and the second semiconductor chip 120. The first capacitor 13 and the second capacitor 14 are constituted of the plurality of first conductive layers 31 provided on the first substrate surface 20S of the mounting substrate 20 and the plurality of second conductive layers 32 provided in the mounting substrate 20.

In the semiconductor device 10, the first capacitor 13 and the second capacitor 14 are constituted of the plurality of first conductive layers 31 and the plurality of second conductive layers 32 provided to the mounting substrate 20, and thus, it is possible to achieve a cost reduction compared to a configuration in which the first capacitor 13 and the second capacitor 14 are respectively discrete components.

The first capacitor 13 and the second capacitor 14 are constituted of the plurality of first conductive layers 31 and the plurality of second conductive layers 32 provided to the mounting substrate 20, and thus, the first capacitor 13 and the second capacitor 14 can be incorporated into the semiconductor device 10.

The first capacitor 13 and the second capacitor 14 are constituted of the plurality of first conductive layers 31 and the plurality of second conductive layers 32 provided to the mounting substrate 20. Thus, it is possible to configure the semiconductor device 10 by mounting the first semiconductor chip 110 and the second semiconductor chip 120 on the mounting substrate 20, and therefore, it is possible to improve production efficiency for the semiconductor device 10.

The first semiconductor chip 110 is configured to output a first output signal S11 to the first capacitor 13 and output a second output signal S12 to the second capacitor 14. Additionally, the first semiconductor chip 110 is configured to generate the first output signal S11 and the second output signal S12 as differential signals.

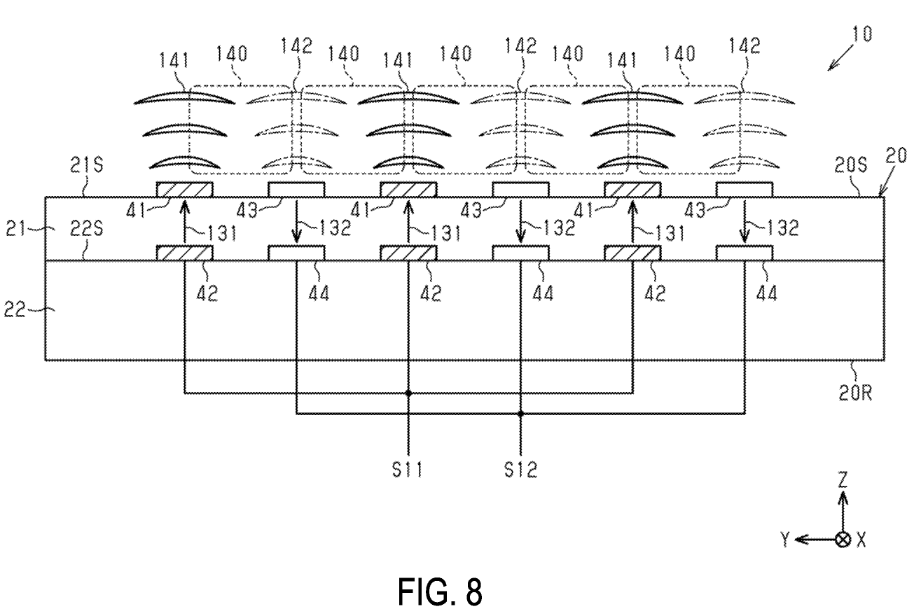

As shown in FIG. 8, the first capacitor 13 is constituted of the plurality of second conductive layers 42 provided in the mounting substrate 20 and the plurality of first conductive layers 41 provided on the first substrate surface 20S of the mounting substrate 20. The second capacitor 14 is constituted of the plurality of fourth conductive layers 44 provided in the mounting substrate 20 and the plurality of third conductive layers 43 provided on the first substrate surface 20S of the mounting substrate 20.

The first output signal S11 is supplied to the plurality of second conductive layers 42, and the second output signal S12 is supplied to the plurality of fourth conductive layers 44. The first output signal S11 and the second output signal S12 are differential signals. Thus, an electric field 131 between the first conductive layer 41 and the second conductive layer 42 faces the opposite direction in the third direction Z to an electric field 132 between the third conductive layer 43 and the fourth conductive layer 44. As an example, the electric fields 131 and 132 for when the first output signal S11 is at an H level and the second output signal S12 is at an L level are shown.

Through transmission of the first output signal S11, in the first capacitor 13, first radiation noise 141 is generated in the plurality of first conductive layers 41 and the plurality of second conductive layers 42, respectively. Similarly, through transmission of the second output signal S12, in the second capacitor 14, second radiation noise 142 is generated in the plurality of third conductive layers 43 and the plurality of fourth conductive layers 44, respectively. The first output signal S11 and the second output signal S12 are differential signals, and thus, the phase of the second radiation noise 142 is inverted in relation to the phase of the first radiation noise 141. Thus, in a plurality of regions 140 where the first conductive layers 41 and the third conductive layers 43 are adjacent to each other, the first radiation noise 141 and the second radiation noise 142 cancel each other out.

In FIG. 8, for ease of explanation, radiation noises 141 and 142 that are directed upward in relation to the conductive layers 41, 42, 43, and 44 are shown. For radiation noises radiated from the surfaces of the conductive layers 41, 42, 43, and 44, similar to what was described above, the first radiation noise 141 and the second radiation noise 142 cancel each other out in regions where the conductive layers are adjacent to each other.

### Comparison Example

Here, a comparison example to Embodiment 1 will be described.

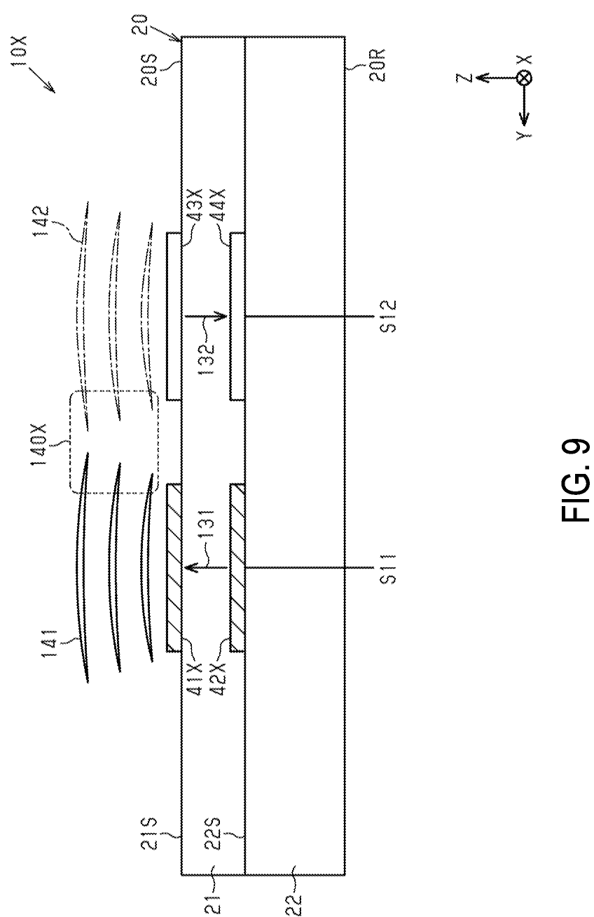

FIG. 9 is a cross-sectional view of a semiconductor device 10X according to a comparison example. FIG. 9 corresponds to the cross-sectional view of the semiconductor device 10 shown in FIG. 8. For the semiconductor device 10X of the comparison example shown in FIG. 9, constituent elements corresponding to the semiconductor device 10 of the embodiment shown in FIG. 8 are given the same names and reference characters.

FIG. 9 is a schematic cross-sectional view showing the arrangement of a first capacitor 13 and a second capacitor 14 in the semiconductor device 10X of the comparison example. FIG. 9 shows a cross-sectional structure corresponding to FIG. 5.

In the semiconductor device 10X of the comparison example, the first capacitor 13 is constituted of one first conductive layer 41X and one second conductive layer 42X. The first conductive layer 41X and the second conductive layer 42X oppose each other in the third direction Z.

The second capacitor 14 is constituted of one third conductive layer 43X and one fourth conductive layer 44X. The third conductive layer 43X and the fourth conductive layer 44X oppose each other in the third direction Z.

The first output signal S11 is supplied to the second conductive layer 42X, and the second output signal S12 is supplied to the fourth conductive layer 44X. The first output signal S11 and the second output signal S12 are differential signals. Thus, an electric field 131 between the first conductive layer 41X and the second conductive layer 42X faces the opposite direction in the third direction Z to an electric field 132 between the third conductive layer 43X and the fourth conductive layer 44X. As an example, the electric fields 131 and 132 for when the first output signal S11 is at an H level and the second output signal S12 is at an L level are shown.

Through transmission of the first output signal S11, in the first capacitor 13, first radiation noise 141 is generated. Similarly, through transmission of the second output signal S12, in the second capacitor 14, second radiation noise 142 is generated. The first output signal S11 and the second output signal S12 are differential signals, and thus, the phase of the second radiation noise 142 is inverted in relation to the phase of the first radiation noise 141. Thus, the first radiation noise 141 and the second radiation noise 142 cancel each other out only in one region 140X where the first conductive layer 41X and the second conductive layer 42X are adjacent to the third conductive layer 43X and the fourth conductive layer 44X.

As described above, in the semiconductor device 10 of Embodiment 1, the first radiation noise 141 and the second radiation noise 142 cancel each other out in the plurality of regions 140 where the plurality of first conductive layers 41 and the plurality of third conductive layers 43 are adjacent to each other. Thus, it is possible to reduce radiation noise with the semiconductor device 10 of Embodiment 1.

### Effects of Embodiment 1

As described above, the present embodiment exhibits the following effects.

(1-1) The semiconductor device 10 includes the mounting substrate 20, the first semiconductor chip 110, and the second semiconductor chip 120. The mounting substrate 20 includes the first substrate surface 20S and the second substrate surface 20R opposite to the first substrate surface 20S. The first semiconductor chip 110 is mounted on the first substrate surface 20S of the mounting substrate 20. The second semiconductor chip 120 is mounted on the first substrate surface 20S of the mounting substrate 20 at a gap from the first semiconductor chip 110. The plurality of first conductive layers 31 are provided on the first substrate surface 20S of the mounting substrate 20, and the plurality of second conductive layers 32 are provided in the mounting substrate 20. The semiconductor device 10 includes the first capacitor 13 and the second capacitor 14 that are electrically connected to the first semiconductor chip 110 and the second semiconductor chip 120. The first capacitor 13 and the second capacitor 14 are constituted of the plurality of first conductive layers 31 provided on the first substrate surface 20S of the mounting substrate 20 and the plurality of second conductive layers 32 provided in the mounting substrate 20.

In the semiconductor device 10, the first capacitor 13 and the second capacitor 14 are constituted of the plurality of first conductive layers 31 and the plurality of second conductive layers 32 provided to the mounting substrate 20, and thus, it is possible to achieve a cost reduction compared to a configuration in which the first capacitor 13 and the second capacitor 14 are respectively discrete components.

(1-2) The first capacitor 13 and the second capacitor 14 are constituted of the plurality of first conductive layers 31 and the plurality of second conductive layers 32 provided to the mounting substrate 20, and thus, the first capacitor 13 and the second capacitor 14 can be incorporated into the semiconductor device 10.

(1-3) The first capacitor 13 and the second capacitor 14 are constituted of the plurality of first conductive layers 31 and the plurality of second conductive layers 32 provided to the mounting substrate 20. Thus, it is possible to configure the semiconductor device 10 by mounting the first semiconductor chip 110 and the second semiconductor chip 120 on the mounting substrate 20, and therefore, it is possible to improve production efficiency for the semiconductor device 10.

(1-4) The first semiconductor chip 110 is configured to output a first output signal S11 to the first capacitor 13 and output a second output signal S12 to the second capacitor 14. Additionally, the first semiconductor chip 110 is configured to generate the first output signal S11 and the second output signal S12 as differential signals. According to this configuration, it is possible to reduce radiation noise with the semiconductor device 10.

### Embodiment 2

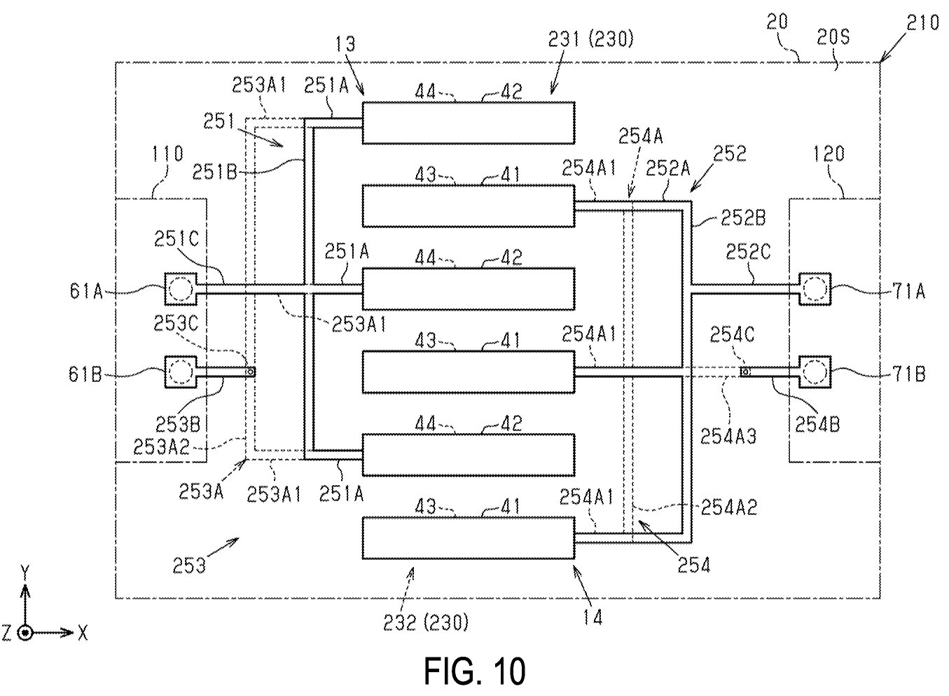

A semiconductor device 210 according to Embodiment 2 will be described below with reference to FIGS. 10 to 13.

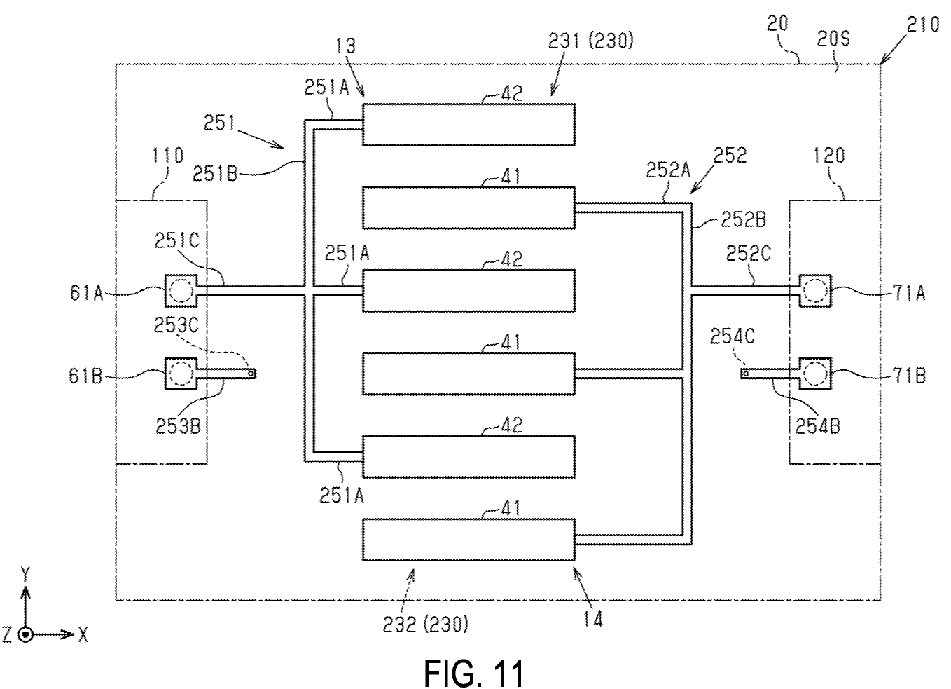

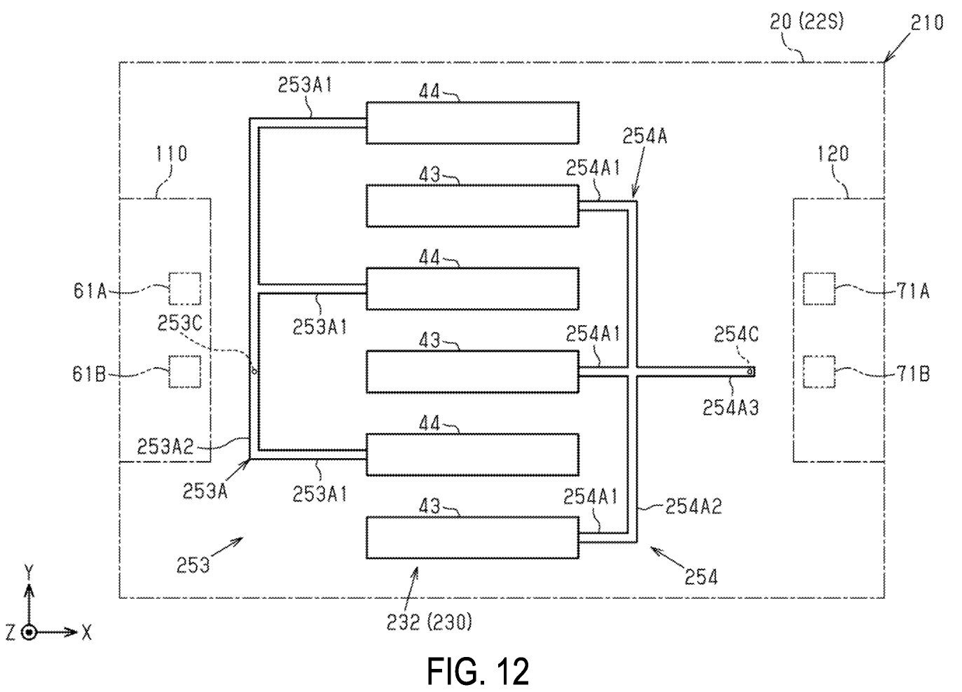

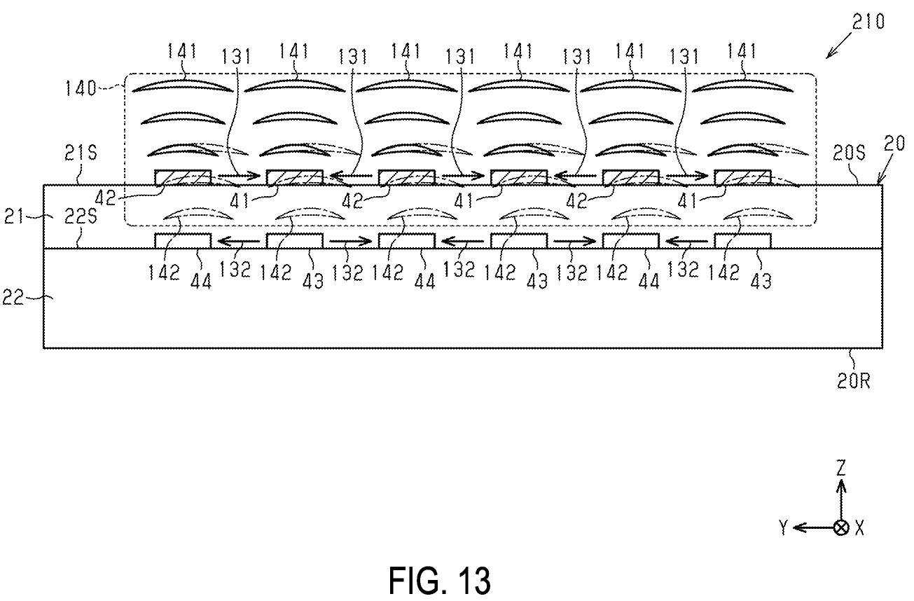

FIG. 10 is a magnified schematic plan view of a portion of the semiconductor device according to Embodiment 2, and shows the first capacitor 13, the second capacitor 14, and connective wiring lines 251 to 254. FIG. 11 is a schematic plan view of a conductive layer and wiring lines provided on a first substrate surface 20S of a mounting substrate 20. FIG. 12 is a schematic plan view of a conductive layer and wiring lines provided inside the mounting substrate 20. FIG. 13 is a schematic cross-sectional view for describing the action of the semiconductor device.

For the semiconductor device 210 of Embodiment 2, constituent elements similar to those of the semiconductor device 10 of Embodiment 1 are assigned the same reference characters. Below, description of constituent elements similar to those of Embodiment 1 will be omitted, and constituent elements differing from those of Embodiment 1 will be described.

The semiconductor device 210 of Embodiment 2 differs from the semiconductor device 10 of Embodiment 1 in terms of the arrangement of the conductive layers constituting the first capacitor 13 and the second capacitor 14, and the configuration of the connective wiring lines connecting the first capacitor 13 and the second capacitor 14 to the first semiconductor chip 110 and the second semiconductor chip 120.

### First Capacitor, Second Capacitor

As shown in FIGS. 10 to 12, the semiconductor device 210 includes the first capacitor 13 and the second capacitor 14. The first capacitor 13 and the second capacitor 14 are disposed between the first semiconductor chip 110 and the second semiconductor chip 120 along the first direction X in which the first semiconductor chip 110 and the second semiconductor chip 120 are arranged.

The first capacitor 13 and the second capacitor 14 are constituted of a plurality of conductive layers 230 provided to the mounting substrate 20. The plurality of conductive layers 230 include a plurality of first conductive layers 231 provided on the first substrate surface 20S of the mounting substrate 20 and a plurality of second conductive layers 232 provided in the mounting substrate 20. As shown in FIG. 12, the plurality of second conductive layers 232 are provided on the first surface 22S of the second insulating layer 22.

The plurality of first conductive layers 231 include a plurality of first conductive layers 41 and a plurality of second conductive layers 42. The plurality of first conductive layers 41 and the plurality of second conductive layers 42 have a rectangular shape in a plan view. The plurality of first conductive layers 41 and the plurality of second conductive layers 42 have a rectangular shape that is elongated in the first direction X along which the first semiconductor chip 110 and the second semiconductor chip 120 are arrayed. The plurality of first conductive layers 41 and the plurality of second conductive layers 42 are arranged alternately along the second direction Y, which is perpendicular to the first direction X. The plurality of first conductive layers 41 and the plurality of second conductive layers 42 have the same size in one example.

The plurality of second conductive layers 232 include a plurality of third conductive layers 43 and a plurality of fourth conductive layers 44. The plurality of third conductive layers 43 and the plurality of fourth conductive layers 44 have a rectangular shape in a plan view. The plurality of third conductive layers 43 and the plurality of fourth conductive layers 44 have a rectangular shape that is elongated in the first direction X along which the first semiconductor chip 110 and the second semiconductor chip 120 are arrayed. The plurality of third conductive layers 43 and the plurality of fourth conductive layers 44 are arranged alternately along the second direction Y, which is perpendicular to the first direction X. The plurality of third conductive layers 43 and the plurality of fourth conductive layers 44 have the same size in one example.

The plurality of first conductive layers 41 and the plurality of second conductive layers 42 have the same size in one example. The plurality of first conductive layers 41 and the plurality of second conductive layers 42 are arranged so as to overlap each other in the second direction Y. The plurality of first conductive layers 41 and the plurality of second conductive layers 42 oppose each other in the second direction Y.

The plurality of third conductive layers 43 and the plurality of fourth conductive layers 44 have the same size in one example. The plurality of third conductive layers 43 and the plurality of fourth conductive layers 44 are arranged so as to overlap each other in the second direction Y. The plurality of third conductive layers 43 and the plurality of fourth conductive layers 44 oppose each other in the second direction Y.

The first capacitor 13 is constituted of the plurality of first conductive layers 41 and the plurality of second conductive layers 42 that oppose each other in the second direction Y. The first capacitor 13 is constituted of the plurality of first conductive layers 41 and the plurality of second conductive layers 42 provided on the first substrate surface 20S of the mounting substrate 20.

The second capacitor 14 is constituted of the plurality of third conductive layers 43 and the plurality of fourth conductive layers 44 that oppose each other in the second direction Y. The second capacitor 14 is constituted of the plurality of third conductive layers 43 and the plurality of fourth conductive layers 44 provided in the mounting substrate 20 (first surface 22S of second insulating layer 22).

### Connective Wiring Lines

As shown in FIGS. 10 to 12, the semiconductor device 210 includes a first connective wiring line 251 that electrically connects the first semiconductor chip 110 to the first capacitor 13, and a second connective wiring line 252 that electrically connects the first capacitor 13 to the second semiconductor chip 120.

As shown in FIGS. 10 and 11, the first connective wiring line 251 electrically connects the plurality of second conductive layers 42 constituting the first capacitor 13 to one first connection pad 61A among the plurality of first connection pads 61 on which the first semiconductor chip 110 is mounted. The second connective wiring line 252 electrically connects the plurality of first conductive layers 41 constituting the first capacitor 13 to one second connection pad 71A among the plurality of second connection pads 71 on which the second semiconductor chip 120 is mounted.

The first connective wiring line 251 is provided on the first surface 21S of the first insulating layer 21. The first connective wiring line 251 includes a plurality of wiring sections 251A that extend from the plurality of second conductive layers 42 in the first direction X, a wiring section 251B that extends in the second direction Y and connects the tips of the plurality of wiring sections 251A, and a wiring section 251C that connects the wiring section 251B to the first connection pad 61A.

The second connective wiring line 252 is provided on the first surface 21S of the first insulating layer 21. The second connective wiring line 252 includes a plurality of wiring sections 252A that extend from the plurality of first conductive layers 41 in the first direction X, a wiring section 252B that extends in the second direction Y and connects the tips of the plurality of wiring sections 252A, and a wiring section 252C that connects the wiring section 252B to the second connection pad 71A.

The semiconductor device 210 includes a third connective wiring line 253 that electrically connects the first semiconductor chip 110 to the second capacitor 14, and a fourth connective wiring line 254 that electrically connects the second capacitor 14 to the second semiconductor chip 120.

As shown in FIGS. 10 and 12, the third connective wiring line 253 electrically connects the plurality of fourth conductive layers 44 constituting the second capacitor 14 to one first connection pad 61B among the plurality of first connection pads 61 on which the first semiconductor chip 110 is mounted. The fourth connective wiring line 254 electrically connects the plurality of third conductive layers 43 constituting the second capacitor 14 to one second connection pad 71B among the plurality of second connection pads 71 on which the second semiconductor chip 120 is mounted.

The third connective wiring line 253 includes a wiring unit 253A connected to the plurality of fourth conductive layers 44, a wiring unit 253B connected to the first connection pad 61B, and a via 253C that connects the wiring unit 253A and the wiring unit 253B. The wiring unit 253A is provided on the first surface 22S (see FIG. 12) of the second insulating layer 22. The wiring unit 253A includes a plurality of first wiring sections 253A1 that extend from each of the plurality of fourth conductive layers 44 towards the first semiconductor chip 110 in a plan view, and a second wiring section 253A2 that extends in the second direction Y and is connected to the tips of the plurality of first wiring sections 253A1. The wiring unit 253B extends from the first connection pad 61B towards the second semiconductor chip 120. The tip of the wiring unit 253B connected to the first connection pad 61B is positioned further towards the first semiconductor chip 110 (first connection pad 61B) than the second wiring section 251B of the first connective wiring line 251. The via 253C connects the tip of the wiring unit 253B to the second wiring section 253A2.

The fourth connective wiring line 254 includes a wiring unit 254A connected to the plurality of third conductive layers 43, a wiring unit 254B connected to the second connection pad 71B, and a via 254C that connects the wiring unit 254A and the wiring unit 254B. The wiring unit 254A is provided on the first surface 22S (see FIG. 12) of the second insulating layer 22. The wiring unit 254A includes a plurality of first wiring sections 254A1 that extend from each of the plurality of third conductive layers 43 towards the second semiconductor chip 120 in a plan view, a second wiring section 254A2 that extends in the second direction Y and is connected to the tips of the plurality of first wiring sections 254A1, and a third wiring section 254A3 that extends from the second wiring section 254A2 towards the second connection pad 71B in a plan view. The wiring unit 254B extends from the second connection pad 71B towards the first semiconductor chip 110. The tip of the wiring unit 254B connected to the second connection pad 71B is positioned further towards the second semiconductor chip 120 (second connection pad 71B) than the second wiring section 252B of the second connective wiring line 252. The via 254C connects the tip of the wiring unit 254B to the third wiring section 254A3.

### Action of Embodiment 2

As shown in FIG. 13, the plurality of first conductive layers 41 constituting the first capacitor 13 overlap the plurality of third conductive layers 43 constituting the second capacitor 14 in the third direction Z. Thus, in the third direction Z, the first radiation noise 141 emitted from the first conductive layer 41 and the second radiation noise 142 emitted from the third conductive layer cancel each other out. Similarly, the plurality of second conductive layers 42 constituting the first capacitor 13 overlap the plurality of fourth conductive layers 44 constituting the second capacitor 14 in the third direction Z. In FIG. 13, the second radiation noise 142 is depicted as being offset in the second direction Y, thereby making it easier to discern the second radiation noise 142. Thus, in the third direction Z, the first radiation noise 141 emitted from the second conductive layer 42 and the second radiation noise 142 emitted from the fourth conductive layer cancel each other out. Therefore, it is possible to further reduce radiation noise with the semiconductor device 210 of Embodiment 2.

### Effects of Embodiment 2

As described above, Embodiment 2 exhibits the following effects in addition to the effects of Embodiment 1.

(2-1) The plurality of first conductive layers 41 constituting the first capacitor 13 overlap the plurality of third conductive layers 43 constituting the second capacitor 14 in the third direction Z. Thus, in the third direction Z, the first radiation noise 141 emitted from the first conductive layer 41 and the second radiation noise 142 emitted from the third conductive layer cancel each other out. Similarly, the plurality of second conductive layers 42 constituting the first capacitor 13 overlap the plurality of fourth conductive layers 44 constituting the second capacitor 14 in the third direction Z. Thus, in the third direction Z, the first radiation noise 141 emitted from the second conductive layer 42 and the second radiation noise 142 emitted from the fourth conductive layer cancel each other out. Therefore, it is possible to further reduce radiation noise with the semiconductor device 210 of Embodiment 2.

### Embodiment 3

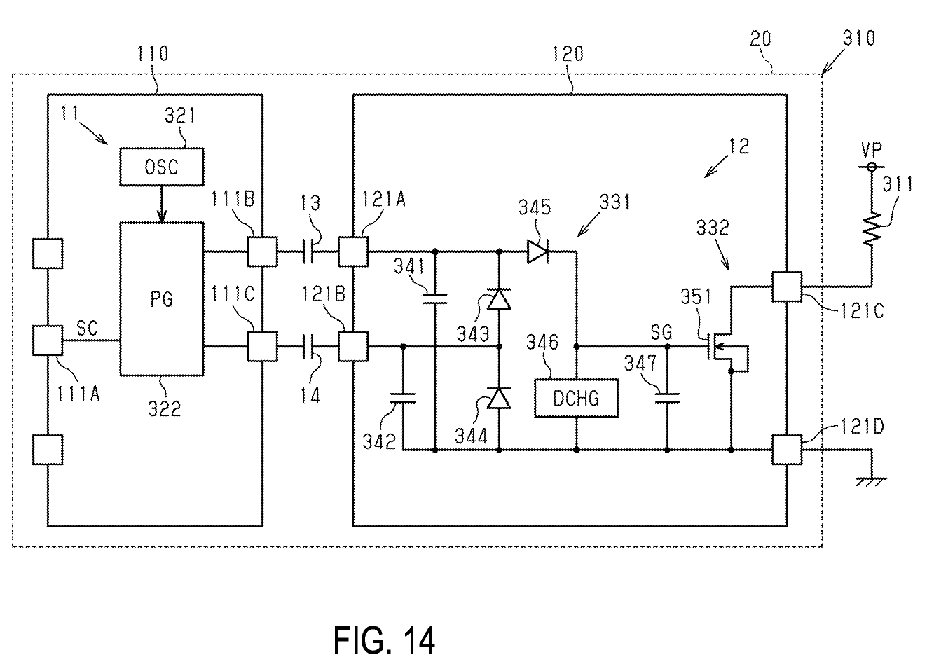

A semiconductor device 310 according to Embodiment 3 will be described below with reference to FIGS. 14 to 16.

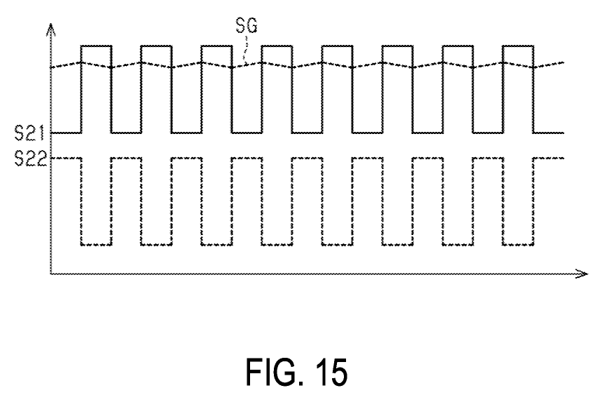

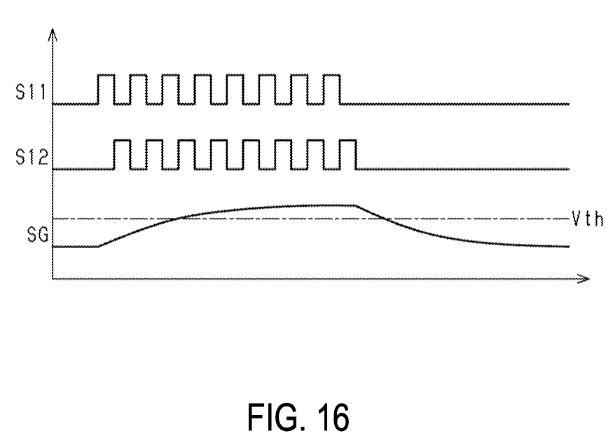

FIG. 14 is a circuit diagram showing a schematic configuration of the semiconductor device 310 according to Embodiment 3. FIGS. 15 and 16 are waveform charts for describing the operation of the semiconductor device 310.

For the semiconductor device 310 of Embodiment3, constituent elements similar to those of the semiconductor device 10 of Embodiment 1 are assigned the same reference characters. Below, description of constituent elements similar to those of Embodiment 1 will be omitted, and constituent elements differing from those of Embodiment 1 will be described. In FIG. 14, the pads provided to the mounting substrate 20 are omitted, and the connective relationship will be described using electrodes of the first semiconductor chip 110 and the second semiconductor chip 120.

The semiconductor device 310 of Embodiment 3 is connected to a load 311, and is used as a switch to control the supply and stoppage of a drive voltage VP to the load 311. The load 311 is electrically connected to a first output electrode 121C of the second semiconductor chip 120. A second output electrode 121D of the second semiconductor chip 120 has supplied thereto a reference voltage (e.g., ground voltage) at a lower potential than the drive voltage VP.

The semiconductor device 310 of Embodiment 3 indicates a configuration example of the primary circuit 11 and the secondary circuit 12.

The semiconductor device 310 of Embodiment 3 includes the mounting substrate 20, and the first semiconductor chip 110 and the second semiconductor chip 120 mounted on the mounting substrate 20. Also, the semiconductor device 310 includes a first capacitor 13 and a second capacitor 14 provided on the mounting substrate 20.

The first semiconductor chip 110 includes a first input electrode 111A, a first output electrode 111B, and a second output electrode 111C. The first input electrode 111A is supplied a control signal SC. The first output electrode 111B is connected to a first terminal (plurality of second conductive layers 42 shown in FIG. 4) of the first capacitor 13, and the second output electrode 111C is connected to a first terminal (plurality of fourth conductive layers 44 shown in FIG. 4) of the second capacitor 14.

The second semiconductor chip 120 includes a first input electrode 121A, a second input electrode 121B, the first output electrode 121C, and the second output electrode 121D. The first input electrode 121A is connected to a second terminal (plurality of first conductive layers 41 shown in FIG. 4) of the first capacitor 13, and the second input electrode 121B is connected to a second terminal (third conductive layers 43 shown in FIG. 4) of the second capacitor 14.

### Primary Circuit

The first semiconductor chip 110 includes the primary circuit 11.

The primary circuit 11 includes an oscillation circuit 321 (OSC) and a pulse generation circuit 322 (PG).

The oscillation circuit 321 outputs a clock signal CLK. The clock signal CLK is a square wave in one example. The clock signal CLK has a prescribed duty at a prescribed frequency. The oscillation circuit 321 may be configured to be able to change the frequency and duty of the clock signal CLK. The oscillation circuit 321 may be configured so as to output or stop the clock signal CLK by an enable signal, for example.

The pulse generation circuit 322 is configured to generate the first output signal S11 and the second output signal S12 on the basis of the clock signal CLK and the control signal SC. Also, the pulse generation circuit 322 is configured to generate the first output signal S11 and the second output signal S12 as differential signals.

The pulse generation circuit 322 generates the first output signal S11 and the second output signal S12, which are differential signals, on the basis of the clock signal CLK when the control signal SC is at an H level, for example. The logic levels of the first output signal S11 and the second output signal S12 change complementarily. Also, the pulse generation circuit 322 generates the first output signal S11 and the second output signal S12 at a prescribed logic level such as an L level when the control signal SC is at an L level, for example .

### Secondary Circuit

The second semiconductor chip 120 includes the secondary circuit 12. In one example, the secondary circuit 12 includes a driver circuit 331 and a switching circuit 332. Alternatively, a configuration may be adopted in which the secondary circuit 12 includes the driver circuit 331 and the switching circuit 332 is included in a semiconductor chip differing from the second semiconductor chip 120.

The driver circuit 331 includes capacitors 341 and 342, diodes 343, 344, and 345, a discharge circuit 346 (DCHG), and a capacitor 347.

A first terminal of the capacitor 341 is connected to the first input electrode 121A and a second terminal of the capacitor 341 is connected to the second output electrode 121D. A first terminal of the capacitor 342 is connected to the second input electrode 121B and a second terminal of the capacitor 342 is connected to the second output electrode 121D. The capacitors 341 and 342 may be parasitic capacitors formed in the second semiconductor chip 120, between a wiring line at reference potential connected to the second output electrode 121D and wiring lines connected to the first and second input electrodes 121A and 121B.

An anode terminal of the diode 343 is connected to the second input electrode 121B and a cathode terminal of the diode 343 is connected to the first input electrode 121A.

An anode terminal of the diode 344 is connected to the second output electrode 121D and a cathode terminal of the diode 344 is connected to the second input electrode 121B.

An anode terminal of the diode 345 is connected to the first input electrode 121A and a cathode terminal of the diode 345 is connected to a gate terminal of a transistor 351 of the switching circuit 332.

A first terminal of the capacitor 347 is connected to the gate terminal of the transistor 351 and a second terminal of the capacitor 347 is connected to the second output electrode 121D. The capacitor 347 may be a parasitic capacitor formed in the second semiconductor chip 120, between a wiring line at reference potential connected to the second output electrode 121D and a wiring line connecting the cathode terminal of the diode 345, the discharge circuit 346, and the transistor 351.

A first terminal of the discharge circuit 346 is connected to the first terminal of the capacitor 347 and a second terminal of the discharge circuit 346 is connected to the second output electrode 121D. The discharge circuit 346 is constituted of a resistor in one example. The discharge circuit 346 discharges the accumulated charge of the capacitor 347.

The switching circuit 332 includes the transistor 351 in one example. The transistor 351 may be an n-channel metal-oxide-semiconductor field effect transistor (MOSFET) in one example. The transistor 351 includes a drain terminal connected to the first output electrode 121C, a source terminal connected to the second output electrode 121D, and the gate terminal connected to the anode terminal of the diode 345.

### Action of Embodiment 3

As shown in FIGS. 15 and 16, the first output signal S11 and the second output signal S12 are differential signals with levels that change complementarily. As a result of the first output signal S11 and the second output signal S12, the first input signal S21 and the second input signal S22 in the second semiconductor chip 120 are differential signals. The diodes 343 and 344 cause the voltage level of the first input signal S21 to increase relative to the voltage level of the second input signal S22. The first input signal S21 is supplied, as the driving signal SG via the diode 345, to the gate terminal of the transistor 351 of the switching circuit 332.

The pulse generation circuit 322 of the first semiconductor chip 110 outputs the first output signal S11 and the second output signal S12 as pulses on the basis of the control signal SC.

As shown in FIG. 16, the driving signal SG rises through generation of the first output signal S11 and the second output signal S12, which are differential signals. When the driving signal SG exceeds a threshold voltage Vth of the transistor 351 of the switching circuit 332, the transistor 351 of the switching circuit 332 enters an ON state.

As shown in FIG. 14, when the transistor 351 enters the ON state, current flows to the load 311, which drives the load 311.

The pulse generation circuit 322 of the first semiconductor chip 110 outputs the first output signal S11 and the second output signal S12 at the L level on the basis of the control signal SC.

As shown in FIG. 16, when the first output signal S11 and the second output signal S12 are at the L level, the driving signal SG decreases due to the discharge circuit 346 shown in FIG. 14. Then, when the driving signal SG falls below the threshold voltage Vth of the transistor 351, the transistor 351 enters an ON state.

### Effects of Embodiment 3

As described above, Embodiment 3 exhibits the following effects in addition to the effects of Embodiment 1.

(3-1) In the semiconductor device 310, the primary circuit 11 and the secondary circuit 12 are insulated from each other by the first capacitor 13 and the second capacitor 14, the semiconductor device 310 being configured as an insulating switch that controls whether the switching circuit 332 is in the ON state or the OFF state. In this manner, the semiconductor device 310 configured as the insulating switch can be easily provided.

### Embodiment 4

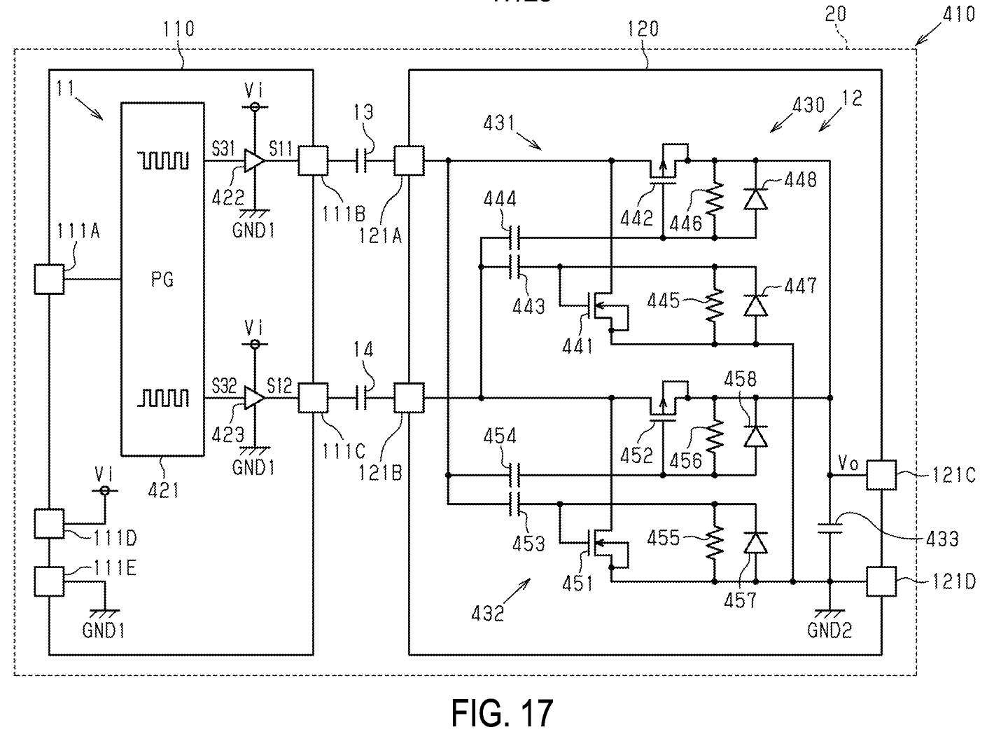

A semiconductor device 410 according to Embodiment 4 will be described below with reference to FIG. 17.

FIG. 17 is a circuit diagram showing the semiconductor device 410 according to Embodiment 4.

For the semiconductor device 410 of Embodiment 4, constituent elements similar to those of the semiconductor device 10 of Embodiment 1 are assigned the same reference characters. Below, description of constituent elements similar to those of Embodiment 1 will be omitted, and constituent elements differing from those of Embodiment 1 will be described. In FIG. 14, the pads provided to the mounting substrate 20 are omitted, and the connective relationship will be described using electrodes of the first semiconductor chip 110 and the second semiconductor chip 120.

The semiconductor device 410 of Embodiment 4 is used as an insulating DC-DC converter that converts an input voltage Vi to an output voltage Vo and outputs the output voltage Vo.

The semiconductor device 410 of Embodiment 4 indicates a configuration example of the primary circuit 11 and the secondary circuit 12.

The semiconductor device 410 of Embodiment 4 includes the mounting substrate 20, and the first semiconductor chip 110 and the second semiconductor chip 120 mounted on the mounting substrate 20. Also, the semiconductor device 410 includes a first capacitor 13 and a second capacitor 14 provided on the mounting substrate 20.

The first semiconductor chip 110 includes a first input electrode 111A, a first output electrode 111B, and a second output electrode 111C. The first input electrode 111A is supplied a control signal SC. The first output electrode 111B is connected to a first terminal (plurality of second conductive layers 42 shown in FIG. 4) of the first capacitor 13, and the second output electrode 111C is connected to a first terminal (plurality of fourth conductive layers 44 shown in FIG. 4) of the second capacitor 14.

The first semiconductor chip 110 includes a second input electrode 111D and a third input electrode 111E. The second input electrode 111D is connected to a power source line to which the input voltage Vi is supplied. The third input electrode 111D is connected to a power source line to which a low potential voltage is supplied. Below, the power source line or the potential of the power source line is referred to as a “first ground GND1.”

The second semiconductor chip 120 includes a first input electrode 121A, a second input electrode 121B, the first output electrode 121C, and the second output electrode 121D. The first input electrode 121A is connected to a second terminal (plurality of first conductive layers 41 shown in FIG. 4) of the first capacitor 13, and the second input electrode 121B is connected to a second terminal (third conductive layers 43 shown in FIG. 4) of the second capacitor 14. The second semiconductor chip 120 outputs the output voltage Vo having the potential difference between the first output electrode 121C and the second output electrode 121D.

### Primary Circuit

The first semiconductor chip 110 includes the primary circuit 11.

The primary circuit 11 includes a pulse generation circuit 421 (PG) and driver circuits 422 and 423.

The pulse generation circuit 421 is configured so as to operate by the input voltage V1 in one example. The pulse generation circuit 421 is configured to generate a first driving signal S31 and a second driving signal S32 on the basis of the control signal SC. The pulse generation circuit 421 is configured to generate the first driving signal S31 and the second driving signal S32 as differential signals. The pulse generation circuit 421 may be configured to generate the first driving signal S31 and the second driving signal S32 by supply of the input voltage Vi, without the control signal SC. Also, the pulse generation circuit 421 may be configured so as to operate by an operating voltage differing from the input voltage V1.

An input terminal of a first driver circuit 422 is supplied the first driving signal S31. An output terminal of the first driver circuit 422 is connected to the first output electrode 111B. The first driver circuit 422 outputs the first output signal S11 in which the level of the input voltage Vi is set to the H level and the level of the first ground GND1 is set to the L level in response to the first driving signal S31.

An input terminal of a second driver circuit 423 is supplied the second driving signal S32. An output terminal of the second driver circuit 423 is connected to the second output electrode 111C. The second driver circuit 423 outputs the second output signal S12 in which the level of the input voltage Vi is set to the H level and the level of the first ground GND1 is set to the L level in response to the second driving signal S32.

### Secondary Circuit

The second semiconductor chip 120 includes the secondary circuit 12.

The secondary circuit 12 includes a rectifier circuit 430. The rectifier circuit 430 rectifies the first input signal S21 and the second input signal S22 inputted by the first capacitor 13 and the second capacitor 14, and generates the output voltage Vo.

The rectifier circuit 430 includes a first rectifier circuit 431, a second rectifier circuit 432, and a smoothing capacitor 433. The first rectifier circuit 431 rectifies the first input signal S21. The second rectifier circuit 432 rectifies the second input signal S22. The smoothing capacitor 433 is connected between the first output electrode 121C and the second output electrode 121D.

The first rectifier circuit 431 includes transistors 441 and 442, capacitors 443 and 444, resistors 445 and 446, and diodes 447 and 448.

A first transistor 441 may be an n-channel metal-oxide-semiconductor field effect transistor (MOSFET) in one example. A second transistor 442 may be a p-channel MOSFET in one example.

A drain terminal of the first transistor 441 is connected to the first input electrode 121A and is supplied the first input signal S21. A source terminal of the first transistor 441 is connected to a wiring line connected to the second output electrode 121D. Below, the wiring line or the potential of the wiring line is referred to as a “second ground GND2.” A first terminal of the first capacitor 443 is connected to the second input electrode 121B, and a second terminal of the first capacitor 443 is connected to a gate terminal of the first transistor 441, a first terminal of a first resistor 445, and a cathode terminal of a first diode 447. A second terminal of the first resistor 445 and an anode terminal of the first diode 447 are connected to the second ground GND2.

A drain terminal of the second transistor 442 is connected to the first input electrode 121A and a source terminal of the second transistor 442 is connected to the second output electrode 121C. A first terminal of the second capacitor 444 is connected to the second input electrode 121B, and a second terminal of the second capacitor 444 is connected to a gate terminal of the second transistor 442, a second terminal of a second resistor 446, and an anode terminal of a second diode 448. A first terminal of the second resistor 446 and a cathode terminal of the second diode 448 are connected to the source terminal of the second transistor.

The second rectifier circuit 432 includes transistors 451 and 452, capacitors 453 and 454, resistors 455 and 456, and diodes 457 and 458.

The third transistor 451 may be an n-channel MOSFET in one example. The fourth transistor 452 may be a p-channel MOSFET in one example.

A drain terminal of the third transistor 451 is connected to the second input electrode 121B and is supplied the second input signal S22. The source terminal of the third transistor 451 is connected to the second ground GND2. A first terminal of the third capacitor 453 is connected to the first input electrode 121A, and a second terminal of the third capacitor 453 is connected to a gate terminal of the third transistor 451, a first terminal of a third resistor 455, and a cathode terminal of a third diode 457. A second terminal of the third resistor 455 and an anode terminal of the third diode 457 are connected to the second ground GND2.

A drain terminal of the fourth transistor 452 is connected to the second input electrode 121B and a source terminal of the fourth transistor 452 is connected to the second output electrode 121C. A first terminal of the fourth capacitor 454 is connected to the first input electrode 121A, and a second terminal of the fourth capacitor 454 is connected to a gate terminal of the fourth transistor 452, a second terminal of a fourth resistor 456, and an anode terminal of a fourth diode 458. A first terminal of the fourth resistor 456 and a cathode terminal of the fourth diode 458 are connected to the source terminal of the fourth transistor.

### Action of Embodiment 4

The first transistor 441 and the second transistor 442 are driven according to the second input signal S22. The third transistor 451 and the fourth transistor 452 are driven according to the first input signal S21.

When the second input signal S22 is at the H level, the gate-source voltages of the first transistor 441 and the second transistor 442 are both higher than the threshold voltage. Thus, the first transistor 441 enters the ON state and the second transistor 442 enters the OFF state. When the first input signal S21 is at the L level, the gate-source voltages of the third transistor 451 and the fourth transistor 452 are both lower than the threshold voltage. Thus, the third transistor 451 enters the OFF state and the fourth transistor 452 enters the ON state.

When the second input signal S22 is at the L level, the gate-source voltages of the first transistor 441 and the second transistor 442 are both lower than the threshold voltage. Thus, the first transistor 441 enters the OFF state and the second transistor 442 enters the ON state. When the first input signal S21 is at the H level, the gate-source voltages of the third transistor 451 and the fourth transistor 452 are both higher than the threshold voltage. Thus, the third transistor 451 enters the ON state and the fourth transistor 452 enters the OFF state.

By the operation of the first transistor 441, the second transistor 442, the third transistor 451, and the fourth transistor 452, the first input signal S21 and the second input signal S22 are rectified. Thus, the output voltage Vo smoothed by the smoothing capacitor 433 is attained.

### Effects of Embodiment 4

As described above, Embodiment 4 exhibits the following effects in addition to the effects of Embodiment 1.

(4-1) In the semiconductor device 410, the primary circuit 11 and the secondary circuit 12 are insulated from each other by the first capacitor 13 and the second capacitor 14, the semiconductor device 410 being configured as an insulating DC-DC converter that outputs the output voltage Vo generated by converting the input voltage Vi. In this manner, the semiconductor device 410 configured as the insulating DC-DC converter can be easily provided.

### Modification Examples

The embodiments above can be modified as described below, for example. The embodiments and the modification examples below can be combined with each other as long as such a combination is technically compatible. In the modification examples below, components in common with the embodiments are assigned the same reference characters as the embodiments, and descriptions thereof are omitted.

The configuration (shape, arrangement position, etc.) of the plurality of conductive layers 30 (31, 32) may be changed as appropriate.

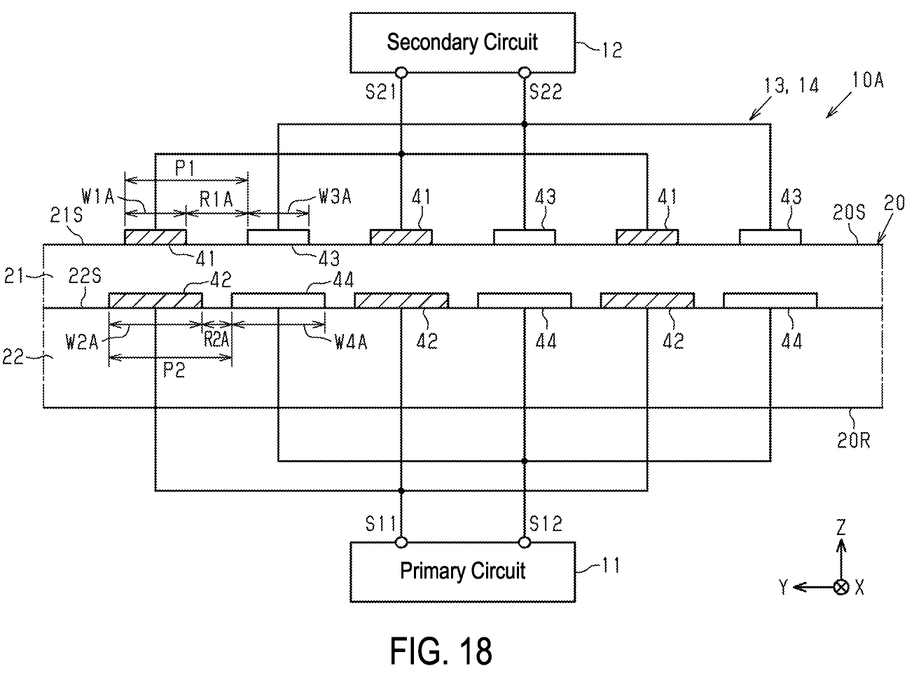

A second width W2A of the second conductive layer 42 may be greater than a first width W1A of the first conductive layer 41 in the manner of a semiconductor device 10A shown in FIG. 18. Similarly, a fourth width W4A of the fourth conductive layer 44 may be greater than a third width W3A of the third conductive layer 43. A second gap R2A between the second conductive layer 42 and the fourth conductive layer 44 may be less than a first gap R1A between the first conductive layer 41 and the third conductive layer 43. The first pitch P1 at which the plurality of first conductive layers 41 and the plurality of third conductive layers 43 are arrayed may be equal to the second pitch P2 at which the plurality of second conductive layers 42 and the plurality of fourth conductive layers 44 are arrayed.

The plurality of second conductive layers 42 are supplied the first output signal S11 from the primary circuit 11. The first output signal S11 is transmitted from the plurality of second conductive layers 42 to the plurality of first conductive layers 41, and is inputted as the first input signal to the secondary circuit 12.

If two wiring lines that respectively transmit two signals are arranged adjacent to each other, then loss can occur in the signal transmission due to a parasitic capacitance formed between the two wiring lines. If transmitting signals by two capacitors, for example, then a secondary wiring line of a capacitor is more heavily impacted by a parasitic capacitance than a primary wiring line, thus resulting in greater loss in signal transmission.

In the first capacitor 13, the second width W2A of the plurality of second conductive layers 42 is greater than the first width W1A of the plurality of first conductive layers 41. Thus, the capacitance of the first capacitor 13 can be ensured. Similarly, in the second capacitor 14, the fourth width W4A of the plurality of fourth conductive layer 44 is greater than the third width W3A of the plurality of third conductive layers 43. Thus, the capacitance of the second capacitor 14 can be ensured. By setting the first gap R1A between the first conductive layer 41 and the third conductive layer 43 to be less than the second gap R2A between the second conductive layer 42 and the fourth conductive layer 44, the parasitic capacitance between the first conductive layer 41 and the third conductive layer 43 can be reduced. As a result, it is possible to reduce the loss in signal transmission between the second semiconductor chip 120 including the secondary circuit 12, and the first capacitor 13 and the second capacitor 14.

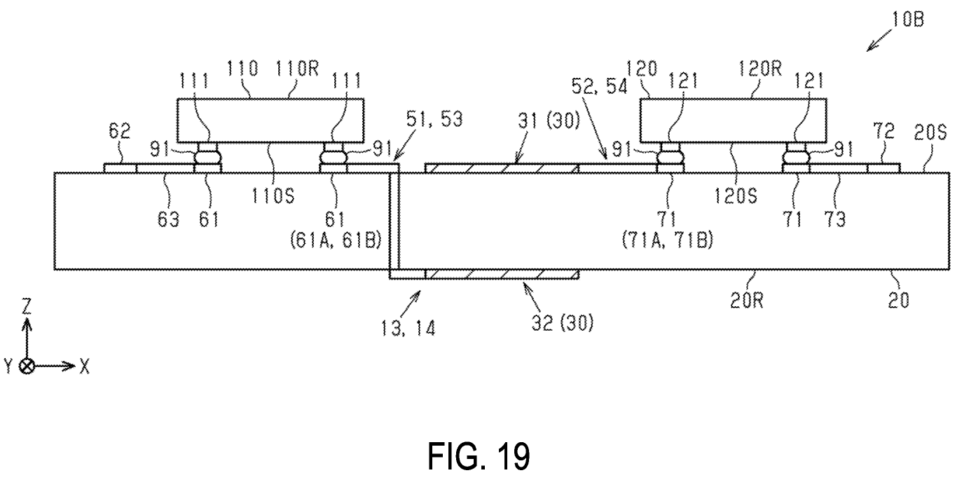

The plurality of second conductive layers 32 may be provided on the second substrate surface 20R of the mounting substrate 20 in the manner of a semiconductor device 10B shown in FIG. 19. The mounting substrate 20 may be constituted of one insulating layer or a plurality of insulating layers. The distance between the first conductive layer 31 and the second conductive layer 32 can be increased as compared to Embodiment 1. By increasing the distance between the first conductive layer 41 and the second conductive layer 42 of the first capacitor 13, it is possible to increase the dielectric breakdown voltage of the first capacitor 13. Similarly, by increasing the distance between the third conductive layer 43 and the fourth conductive layer 44 of the second capacitor 14, it is possible to increase the dielectric breakdown voltage of the second capacitor 14. Meanwhile, by including only the first insulating layer 21 shown in FIG. 3 in the mounting substrate 20, it is possible to form the semiconductor device 10B to be thin.

The mounting method for the first semiconductor chip 110 and the second semiconductor chip 120 may be changed as appropriate.

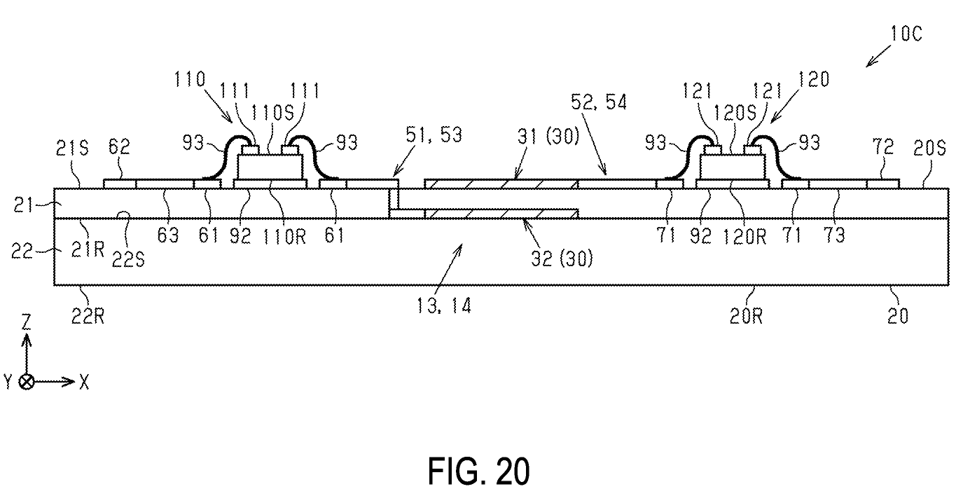

The semiconductor device 10C shown in FIG. 20 includes a conductive wire 93. The first semiconductor chip 110 is electrically connected to the connection pad 61 of the mounting substrate 20 by the conductive wire 93. The second semiconductor chip 120 is electrically connected to the connection pad 71 of the mounting substrate 20 by the conductive wire 93.

In further detail, a mounting electrode 92 is provided on the first substrate surface 20S of the mounting substrate 20. The first semiconductor chip 110 and the second semiconductor chip 120 are arranged such that the second surfaces 110R and 120R face the first substrate surface 20S of the mounting substrate 20. The first semiconductor chip 110 and the second semiconductor chip 120 are mounted over the mounting electrode 92 by a conductive joining material, a non-conductive joining material, or the like. The connection electrode 111 of the first semiconductor chip 110 is electrically connected to the first connection pad 61 by the wire 93. The connection electrode 121 of the second semiconductor chip 110 is electrically connected to the second connection pad 71 by the wire 93.

The first semiconductor chip 110 and the second semiconductor chip 120 may be mounted on the mounting substrate 20 by different methods. For example, a configuration may be adopted in which the first semiconductor chip 110 is mounted with the first surface 110S thereof towards the mounting substrate 20 as shown in FIG. 3, and the second semiconductor chip 120 is mounted with the second surface 120R thereof towards the mounting substrate 20 as shown in FIG. 20.

In the semiconductor device 10 of Embodiment 1, the first output signal S11 is supplied to the plurality of second conductive layers 42, and the second output signal S12 is supplied to the plurality of fourth conductive layers 44. Even with a configuration in which the first output signal S11 is supplied to the plurality of first conductive layers 41 and the second output signal S12 is supplied to the plurality of third conductive layers 43, it is possible to reduce radiation noise in a manner similar to the semiconductor device 10 of Embodiment 1.

The first semiconductor chip 110 and the second semiconductor chip 120 may both be mounted on the second substrate surface 20R of the mounting substrate 20. The first semiconductor chip 110 and the second semiconductor chip 120 may be mounted on different substrate surfaces of the mounting substrate 20. For example, the first semiconductor chip 110 may be mounted on the first substrate surface 20S, with the second semiconductor chip 120 being mounted on the second substrate surface 20R. Alternatively, the first semiconductor chip 110 may be mounted on the second substrate surface 20R, with the second semiconductor chip 120 being mounted on the first substrate surface 20S.

Language used in the present disclosure such as “over” can include both meanings of “on” or “above” as long as the context does not eliminate each of those possibilities. Thus, the expression “the first layer is formed over the second layer” is intended to allow for a given embodiment in which the first layer is directly disposed on the second layer in contact therewith, and another embodiment in which the first layer is disposed above the second layer without being in contact therewith. That is, the term “over” does not eliminate a structure in which another element is formed between the first layer and the second layer.

### Notes

The technical concepts that can be ascertained from the present disclosure will be described below. The constituent elements disclosed in the notes below include the reference characters of the corresponding constituent elements of the embodiments in order to aid understanding, rather than to limit the invention. The reference characters indicate examples to aid understanding, and the constituent elements disclosed in the notes should not be understood as being limited to the constituent elements indicated by the reference characters.

### Note 1

A semiconductor device, including:

a mounting substrate (20) including a first substrate surface (20S) and a second substrate surface (20R) on a side opposite to the first substrate surface (20S);

a first semiconductor chip (110) mounted on the first substrate surface (20S) or the second substrate surface (20R);

a second semiconductor chip (120) mounted on the first substrate surface (20S) or the second substrate surface (20R), at a gap from the first semiconductor chip (110);

a plurality of conductive layers (31) provided on the first substrate surface (20S);

a plurality of conductive layers (32) provided in the mounting substrate (20) or on the second substrate surface (20R); and

a first capacitor (13) and a second capacitor (14) that are constituted of the plurality of conductive layers (31) provided on the first substrate surface (20S) and the plurality of conductive layers (32) provided in the mounting substrate (20) or on the second substrate surface (20R), and that are electrically connected to the first semiconductor chip (110) and the second semiconductor chip (120).

### Note 2

The semiconductor device according to Note 1,

wherein the first capacitor (13) and the second capacitor (14) are disposed between the first semiconductor chip (110) and the second semiconductor chip (120) along a direction (X) in which the first semiconductor chip (110) and the second semiconductor chip (120) are arranged, as viewed from a thickness direction (Z) perpendicular to the first substrate surface (20S).

### Note 3

The semiconductor device according to Note 1 or 2,

wherein the plurality of conductive layers provided on the first substrate surface (20S) include a plurality of first conductive layers (41) and a plurality of third conductive layers (43),

wherein the plurality of first conductive layers (41) and the plurality of third conductive layers (43) extend along a first direction (X) as viewed from a thickness direction (Z) perpendicular to the first substrate surface (20S), and are arranged alternately in a second direction (Y) intersecting with the first direction (X) as viewed from the thickness direction (Z),

wherein the plurality of conductive layers provided in the mounting substrate (20) or on the second substrate surface (20R) include a plurality of second conductive layers (42) and a plurality of fourth conductive layers (44),

wherein the plurality of second conductive layers (42) are arranged so as to face the plurality of first conductive layers (41) in the thickness direction (Z),

wherein the plurality of fourth conductive layers (44) are arranged so as to face the plurality of third conductive layers (43) in the thickness direction (Z),

wherein the first capacitor (13) is constituted of the plurality of first conductive layers (41) and the plurality of second conductive layers (42), and

wherein the second capacitor (14) is constituted of the plurality of third conductive layers (43) and the plurality of fourth conductive layers (44).

### Note 4

The semiconductor device according to Note 3, further including:

a first connective wiring line (51) that electrically connects the plurality of second conductive layers (42) to each other, and electrically connects the plurality of second conductive layers (42) to the first semiconductor chip (110); and

a second connective wiring line (52) that electrically connects the plurality of first conductive layers (41) to each other, and electrically connects the plurality of first conductive layers (41) to the second semiconductor chip (120).

### Note 5

The semiconductor device according to Note 4, further including:

a third connective wiring line (53) that electrically connects the plurality of fourth conductive layers (44) to each other, and electrically connects the plurality of fourth conductive layers (44) to the first semiconductor chip (110); and

a fourth connective wiring line (54) that electrically connects the plurality of third conductive layers (43) to each other, and electrically connects the plurality of third conductive layers (43) to the second semiconductor chip (120).

### Note 6

The semiconductor device according to any one of Notes 3 to 5,

wherein a width (W1) of the first conductive layer (41) is greater than a gap (R1) between the first conductive layer (41) and the third conductive layer (43).

### Note 7

The semiconductor device according to any one of Notes 3 to 5,

wherein a gap (R1) between the first conductive layer (41) and the third conductive layer (43) is greater than a width (W1) of the first conductive layer (41).

### Note 8

The semiconductor device according to any one of Notes 3 to 7,

wherein a distance (D1) between the first conductive layer (41) and the second conductive layer (42) is greater than a pitch (P1) between the plurality of conductive layers (31) provided on the first substrate surface (20S).

### Note 9

The semiconductor device according to any one of Notes 3 to 7,

wherein a distance (D1) between the first conductive layer (41) and the second conductive layer (42) is less than a pitch (P1) between the plurality of conductive layers (31) provided on the first substrate surface (20S).

### Note 10

The semiconductor device according to any one of Notes 3 to 9,

wherein a width (W2A) of the second conductive layer (42) is greater than a width (W1A) of the first conductive layer (41).

### Note 11

The semiconductor device according to any one of Notes 3 to 10,

wherein a gap (R2A) between the second conductive layer (42) and the fourth conductive layer (44) is narrower than a gap (R1A) between the first conductive layer (41) and the third conductive layer (43).

### Note 12

The semiconductor device according to any one of Notes 3 to 11,

wherein, in the second direction (Y), a width (W1) of the first conductive layer (41) is equal to a width (W3) of the third conductive layer (43), and a width (W2) of the second conductive layer (42) is equal to a width (W4) of the fourth conductive layer (44).

### Note 13

The semiconductor device according to Note 1 or 2,

wherein the plurality of conductive layers (231) provided on the first substrate surface (20S) include a plurality of first conductive layers (41) and a plurality of second conductive layers (42),

wherein the plurality of first conductive layers (41) and the plurality of second conductive layers (42) extend along a first direction (X) as viewed from a thickness direction (Z) perpendicular to the first substrate surface (20S), and are arranged alternately in a second direction (Y) intersecting with the first direction (X) as viewed from the thickness direction (Z),

wherein the plurality of conductive layers (232) provided in the mounting substrate (20) or on the second substrate surface (20R) include a plurality of third conductive layers (43) and a plurality of fourth conductive layers (44),

wherein the plurality of third conductive layers (43) are arranged so as to face the plurality of first conductive layers (41) in the thickness direction (Z),

wherein the plurality of fourth conductive layers (44) are arranged so as to face the plurality of second conductive layers (42) in the thickness direction (Z),

wherein the first capacitor (13) is constituted of the plurality of first conductive layers (41) and the plurality of second conductive layers (42), and

wherein the second capacitor (14) is constituted of the plurality of third conductive layers (43) and the plurality of fourth conductive layers (44).

### Note 14

The semiconductor device according to Note 13, further including:

a first connective wiring line (251) that electrically connects the plurality of second conductive layers (42) to each other, and electrically connects the plurality of second conductive layers (42) to the first semiconductor chip (110); and

a second connective wiring line (252) that electrically connects the plurality of first conductive layers (41) to each other, and electrically connects the plurality of first conductive layers (41) to the second semiconductor chip (120),

wherein the first connective wiring line (251) and the second connective wiring line (252) are provided on the first substrate surface (20S).

### Note 15

The semiconductor device according to Note 14, further including:

a third connective wiring line (253) that electrically connects the plurality of fourth conductive layers (44) to each other, and electrically connects the plurality of fourth conductive layers (44) to the first semiconductor chip (110); and

a fourth connective wiring line (254) that electrically connects the plurality of third conductive layers (43) to each other, and electrically connects the plurality of third conductive layers (43) to the second semiconductor chip (120).

### Note 16

The semiconductor device according to any one of Notes 13 to 15,

wherein a width of the first conductive layer (41) is greater than a gap between the first conductive layer (41) and the second conductive layer (42).

### Note 17

The semiconductor device according to any one of Notes 13 to 15,

wherein a gap between the first conductive layer (41) and the second conductive layer (42) is greater than a width of the first conductive layer (41).

### Note 18

The semiconductor device according to any one of Notes 13 to 17,

wherein a distance between the first conductive layer (41) and the third conductive layer (43) is greater than an array pitch between the plurality of conductive layers provided on the first substrate surface (20S).

### Note 19

The semiconductor device according to any one of Notes 13 to 17,

wherein a distance between the first conductive layer (41) and the third conductive layer (43) is less than a pitch between the plurality of conductive layers provided on the first substrate surface (20S).

### Note 20

The semiconductor device according to any one of Notes 1 to 19,

wherein the first semiconductor chip (110) is configured to output a first output signal (S11) to the first capacitor (13) and to output a second output signal (S12) to the second capacitor (14), and to generate the first output signal (S11) and the second output signal (S12) as differential signals.

### Note 21

The semiconductor device according to Note 20,

wherein the second semiconductor chip (120) is configured to operate by a first input signal (S21) inputted by the first capacitor (13) according to the first output signal, and by a second input signal (S22) inputted by the second capacitor (14) according to the second output signal.

### Note 22

The semiconductor device according to Note 21,

wherein the first semiconductor chip (110) includes a signal generation circuit (322) that generates the first output signal and the second output signal, and

wherein the second semiconductor chip (120) includes a driver circuit (331) configured to generate a driving signal according to the first input signal and the second input signal.

### Note 23

The semiconductor device according to Note 21,

wherein the first semiconductor chip (110) includes a signal generation circuit (421) that generates the first output signal and the second output signal, and

wherein the second semiconductor chip (120) includes a rectifier circuit (430) configured to generate an output voltage according to the first input signal and the second input signal.

### Note 24

The semiconductor device according to any one of Notes 1 to 23,

wherein a capacitance of the first capacitor (13) is 20pF to 200pF, inclusive, and

wherein a capacitance of the second capacitor (14) is 20pF to 200pF, inclusive.

### Note 25

The semiconductor device according to any one of Notes 1 to 24,

wherein the mounting substrate (20) is a glass epoxy substrate.

### Note 26

The semiconductor device according to any one of Notes 1 to 25,

wherein connection pads are provided on the first substrate surface (20S), and

wherein, in both the first semiconductor chip (110) and the second semiconductor chip (120), electrodes provided to the first semiconductor chip (110) and the second semiconductor chip (120) are electrically connected to the connection pads by a conductive joining material.

### Note 27

The semiconductor device according to any one of Notes 1 to 25,

wherein connection pads are provided on the first substrate surface (20S), and

wherein both the first semiconductor chip (110) and the second semiconductor chip (120) are electrically connected to the connection pads by a connecting member.

The descriptions above are merely examples. Aside from the constituent elements and methods (manufacturing processes) cited above for the purpose of explaining the techniques of the present disclosure, a person having ordinary skill in the art would understand that more combinations and replacements could be conceived of. The present disclosure is intended to encompass all replacements, changes, and modifications included in the scope of the present disclosure including the claims.

What is claimed is:

1. A semiconductor device, comprising:
a mounting substrate including a first substrate surface and a second substrate surface on a side opposite to the first substrate surface;
a first semiconductor chip mounted on the first substrate surface or the second substrate surface;
a second semiconductor chip mounted on the first substrate surface or the second substrate surface, at a gap from the first semiconductor chip;
a plurality of conductive layers provided on the first substrate surface;
a plurality of conductive layers provided in the mounting substrate or on the second substrate surface; and
a first capacitor and a second capacitor that are constituted of the plurality of conductive layers provided on the first substrate surface and the plurality of conductive layers provided in the mounting substrate or on the second substrate surface, and that are electrically connected to the first semiconductor chip and the second semiconductor chip.

2. The semiconductor device according to claim 1,
wherein the first capacitor and the second capacitor are disposed between the first semiconductor chip and the second semiconductor chip along a direction in which the first semiconductor chip and the second semiconductor chip are arranged, as viewed from a thickness direction perpendicular to the first substrate surface.

3. The semiconductor device according to claim 1,
wherein the plurality of conductive layers provided on the first substrate surface include a plurality of first conductive layers and a plurality of third conductive layers,
wherein the plurality of first conductive layers and the plurality of third conductive layers extend along a first direction as viewed from a thickness direction perpendicular to the first substrate surface, and are arranged alternately in a second direction intersecting with the first direction as viewed from the thickness direction,
wherein the plurality of conductive layers provided in the mounting substrate or on the second substrate surface include a plurality of second conductive layers and a plurality of fourth conductive layers,
wherein the plurality of second conductive layers are arranged so as to face the plurality of first conductive layers in the thickness direction,
wherein the plurality of fourth conductive layers are arranged so as to face the plurality of third conductive layers in the thickness direction,
wherein the first capacitor is constituted of the plurality of first conductive layers and the plurality of second conductive layers, and
wherein the second capacitor is constituted of the plurality of third conductive layers and the plurality of fourth conductive layers.

4. The semiconductor device according to claim 3, further comprising:
a first connective wiring line that electrically connects the plurality of second conductive layers to each other, and electrically connects the plurality of second conductive layers to the first semiconductor chip; and
a second connective wiring line that electrically connects the plurality of first conductive layers to each other, and electrically connects the plurality of first conductive layers to the second semiconductor chip.

5. The semiconductor device according to claim 4, further comprising:
a third connective wiring line that electrically connects the plurality of fourth conductive layers to each other, and electrically connects the plurality of fourth conductive layers to the first semiconductor chip; and
a fourth connective wiring line that electrically connects the plurality of third conductive layers to each other, and electrically connects the plurality of third conductive layers to the second semiconductor chip.

6. The semiconductor device according to claim 3,
wherein a width of a first conductive layer of the plurality of first conductive layers is greater than a gap between the first conductive layer and a third conductive layer of the plurality of third conductive layers.

7. The semiconductor device according to claim 3,
wherein a gap between a first conductive layer of the plurality of first conductive layers and a third conductive layer of the plurality of third conductive layers is greater than a width of the first conductive layer.

8. The semiconductor device according to claim 3,
wherein a distance between a first conductive layer of the plurality of first conductive layers and a second conductive layer of the plurality of second conductive layers is greater than a pitch of the plurality of conductive layers provided on the first substrate surface.

9. The semiconductor device according to claim 3,
wherein a distance between a first conductive layer of the plurality of first conductive layers and a second conductive layer of the plurality of second conductive layers is less than a pitch of the plurality of conductive layers provided on the first substrate surface.

10. The semiconductor device according to claim 3,
wherein a width of a second conductive layer of the plurality of second conductive layers is greater than a width of a first conductive layer of the plurality of first conductive layers.

11. The semiconductor device according to claim 3,
wherein a gap between a second conductive layer of the plurality of second conductive layers and a fourth conductive layer of the plurality of fourth conductive layers is narrower than a gap between a first conductive layer of the plurality of first conductive layers and a third conductive layer of the plurality of third conductive layers.

12. The semiconductor device according to claim 3,
wherein, in the second direction, a width of a first conductive layer of the plurality of first conductive layers is equal to a width of a third conductive layer of the plurality of third conductive layers, and a width of a second conductive layer of the plurality of second conductive layers is equal to a width of a fourth conductive layer of the plurality of fourth conductive layers.

13. The semiconductor device according to claim 1,
wherein the plurality of conductive layers provided on the first substrate surface include a plurality of first conductive layers and a plurality of second conductive layers,
wherein the plurality of first conductive layers and the plurality of second conductive layers extend along a first direction as viewed from a thickness direction perpendicular to the first substrate surface, and are arranged alternately in a second direction intersecting with the first direction as viewed from the thickness direction,
wherein the plurality of conductive layers provided in the mounting substrate or on the second substrate surface include a plurality of third conductive layers and a plurality of fourth conductive layers,
wherein the plurality of third conductive layers are arranged so as to face the plurality of first conductive layers in the thickness direction,
wherein the plurality of fourth conductive layers are arranged so as to face the plurality of second conductive layers in the thickness direction,
wherein the first capacitor is constituted of the plurality of first conductive layers and the plurality of second conductive layers, and
wherein the second capacitor is constituted of the plurality of third conductive layers and the plurality of fourth conductive layers.

14. The semiconductor device according to claim 13, further comprising:
a first connective wiring line that electrically connects the plurality of second conductive layers to each other, and electrically connects the plurality of second conductive layers to the first semiconductor chip; and
a second connective wiring line that electrically connects the plurality of first conductive layers to each other, and electrically connects the plurality of first conductive layers to the second semiconductor chip,
wherein the first connective wiring line and the second connective wiring line are provided on the first substrate surface.

15. The semiconductor device according to claim 14, further comprising:
a third connective wiring line that electrically connects the plurality of fourth conductive layers to each other, and electrically connects the plurality of fourth conductive layers to the first semiconductor chip; and
a fourth connective wiring line that electrically connects the plurality of third conductive layers to each other, and electrically connects the plurality of third conductive layers to the second semiconductor chip,
wherein the third connective wiring line includes a bypass section that bypasses the first connective wiring line in the thickness direction so as not to be in contact with the first connective wiring line, and
wherein the fourth connective wiring line includes a bypass section that bypasses the second connective wiring line in the thickness direction so as not to be in contact with the second connective wiring line.

16. The semiconductor device according to claim 13,
wherein a width of a first conductive layer of the plurality of first conductive layers is greater than a gap between the first conductive layer and a second conductive layer of the plurality of second conductive layers.

17. The semiconductor device according to claim 13,
wherein a gap between a first conductive layer of the plurality of first conductive layers and a second conductive layer of the plurality of second conductive layers is greater than a width of the first conductive layer.

18. The semiconductor device according to claim 13,
wherein a distance between a first conductive layer of the plurality of first conductive layers and a third conductive layer of the plurality of third conductive layers is greater than an array pitch of the plurality of conductive layers provided on the first substrate surface.

19. The semiconductor device according to claim 13,
wherein a distance between a first conductive layer of the plurality of first conductive layers and a third conductive layer of the plurality of third conductive layers is less than a pitch of the plurality of conductive layers provided on the first substrate surface.

20. The semiconductor device according to claim 1,
wherein the first semiconductor chip is configured to output a first output signal to the first capacitor and to output a second output signal to the second capacitor, and to generate the first output signal and the second output signal as differential signals.
